(19) United States
(12) Patent Application Publication
(10) Pub. No.: US 2025/0234765 A1
(43) Pub. Date: Jul. 17, 2025

(54) DISPLAY DEVICE AND METHOD OF FABRICATING THE SAME

(71) Applicant: Samsung Display Co., LTD., Yongin-si (KR)

(72) Inventors: Seung Hyun PARK, Yongin-si (KR); Da Hye KIM, Yongin-si (KR); Nam Wook LEE, Yongin-si (KR)

(73) Assignee: Samsung Display Co., LTD., Yongin-si (KR)

(21) Appl. No.: 18/813,664

(22) Filed: Aug. 23, 2024

(30) Foreign Application Priority Data
Jan. 16, 2024 (KR) 10-2024-0006410

(51) Int. Cl. H10K 59/88; H10K 59/12; H10K 59/122; H10K 59/38; H10K 59/80; H10K 102/00

(52) U.S. Cl. CPC H10K 59/88; H10K 59/1201; H10K 59/122; H10K 59/38; H10K 59/873; H10K 2102/351

(57) ABSTRACT

A display device capable of improving image quality and a method of fabricating the display device. The display device may include a substrate, a first electrode on the substrate, a pixel defining layer on the first electrode, a dummy layer disposed on an uppermost surface of the pixel defining layer, a light emitting layer on the first electrode and the dummy layer; and a second electrode on the light emitting layer, wherein an angle between a lower surface of the dummy layer which faces the pixel defining layer and a side surface of the dummy layer adjacent to the lower surface of the dummy layer may be an acute angle.

### CROSS-REFERENCE TO RELATED APPLICATIONS

This application claims priority under 35 U.S.C. § 119 from Korean Patent Application No. 10-2024-0006410 filed on Jan. 16, 2024 in the Korean Intellectual Property Office, the entire contents of which are incorporated herein by reference.

### BACKGROUND

### 1. Technical Field

The disclosure relates to a display device capable of improving image quality and a method of fabricating the display device.

### 2. Description of the Related Art

Display devices are becoming increasingly important with the development of multimedia. Accordingly, various display devices such as liquid crystal display devices (LCDs) and organic light emitting diode display devices (OLEDs) are being developed.

Of the display devices, a self-light emitting display device includes a self-light emitting element such as an organic light emitting diode. The self-light emitting element may include two electrodes facing each other and a light emitting layer disposed between the two electrodes. In case that the self-light emitting element is an organic light emitting diode, electrons and holes provided from the two electrodes may be recombined in the light emitting layer to generate excitons. As the generated excitons change from an excited state to a ground state, light may be emitted.

A display device may include a color conversion element for realizing color by receiving light from an organic light emitting diode. For example, the color conversion element may receive blue light from the organic light emitting diode and emit blue, green and red light so that an image having various colors can be viewed. The color conversion element may be disposed in the form of a separate substrate in the display device or may be integrated (e.g., directly integrated) with elements in the display device.

### SUMMARY

Aspects of the disclosure provide a display device capable of improving image quality and a method of fabricating the display device.

According to an embodiment of the disclosure, a display device may include a first electrode on a substrate, a pixel defining layer on the first electrode, a dummy layer disposed on an uppermost surface of the pixel defining layer, a light emitting layer on the first electrode and the dummy layer, and a second electrode on the light emitting layer, wherein an angle between a lower surface of the dummy layer which faces the pixel defining layer and a side surface of the dummy layer which is adjacent to the lower surface of the dummy layer may be an acute angle.

In an embodiment, the angle between the lower surface and the side surface of the dummy layer may be in a range of about 65 to about 90 degrees.

In an embodiment, the dummy layer may have a trapezoidal cross section.

In an embodiment, the dummy layer may have a width that gradually decreases in a first direction from the lower surface of the dummy layer toward an upper surface of the dummy layer which faces the lower surface.

In an embodiment, the dummy layer may have a yellowish color.

In an embodiment, the pixel defining layer may have a light emitting area disposed to correspond to a portion of the light emitting layer on the first electrode, and the dummy layer may be disposed around the light emitting area in a plan view.

In an embodiment, the pixel defining layer may define a plurality of light emitting areas, and at least a portion of the dummy layer may be disposed between adjacent light emitting areas in a plan view.

In an embodiment, the dummy layer may have a line shape in a plan view.

In an embodiment, the dummy layer may have a dotted shape in a plan view.

In an embodiment, the dummy layer may include an inorganic material.

In an embodiment, the dummy layer may include at least one of SiNx, SiOx, and SiON.

In an embodiment, the dummy layer may have a thickness in a range of about 1000 to about 4000 Å.

In an embodiment, a portion of the light emitting layer on the first electrode and a portion of the light emitting layer on the dummy layer may not be electrically connected.

In an embodiment, the light emitting layer may include a main light emitting layer on the first electrode; and a dummy light emitting layer disposed on the dummy layer, the dummy light emitting layer may be separated from the main light emitting layer.

In an embodiment, a portion of the second electrode that overlaps the first electrode in a plan view may be electrically disconnected from a portion of the second electrode that overlaps the dummy layer in a plan view.

In an embodiment, the second electrode may include a main second electrode disposed on the light emitting layer to overlap the first electrode, and a dummy second electrode disposed on the light emitting layer to overlap the dummy layer, wherein the main second electrode may be electrically disconnected from the dummy second electrode.

In an embodiment, the display device may further include a thin-film encapsulation layer on the second electrode, wherein the thin-film encapsulation layer may cover a broken portion of the light emitting layer.

In an embodiment, the display device may further include a capping layer between the second electrode and the thin-film encapsulation layer, wherein the capping layer may cover the broken portion of the light emitting layer.

In an embodiment, the display device may further include a wavelength conversion member on the thin-film encapsulation layer.

In an embodiment, a portion of the light emitting layer which is disposed along the side surface of the dummy layer may have a smaller thickness than other portions of the light emitting layer.

In an embodiment, a portion of the second electrode which is disposed along the side surface of the dummy layer may have a smaller thickness than other portions of the second electrode.

According to an embodiment of the disclosure, a method of fabricating a display device may include forming a first electrode on a substrate, forming a pixel defining layer on the first electrode, forming a dummy layer on an uppermost surface of the pixel defining layer, forming a light emitting layer on the first electrode and on the dummy layer, and forming a second electrode on the light emitting layer, wherein an angle between a lower surface of the dummy layer which faces the pixel defining layer and a side surface of the dummy layer adjacent to the lower surface of the dummy layer may be an acute angle.

In an embodiment, the forming of the dummy layer may include forming an inorganic material layer by applying an inorganic material to an entire surface of the substrate which includes the first electrode and the pixel defining layer, placing a photoresist pattern on the inorganic material layer; and forming the dummy layer on the uppermost surface of the pixel defining layer by selectively removing the inorganic material layer using the photoresist pattern as a mask.

In an embodiment, the angle between the lower surface and the side surface of the dummy layer may be in a range of about 65 to about 90 degrees.

In an embodiment, the dummy layer may have a trapezoidal cross section.

In an embodiment, the dummy layer may have a width that gradually decreases in a first direction from the lower surface of the dummy layer toward an upper surface of the dummy layer which faces the lower surface.

In an embodiment, the dummy layer may have a yellowish color.

In the display device according to the disclosure, the display device can improve image quality.

The effects of the disclosure are not limited to the aforementioned effects, and various other effects may be included in the disclosure.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a schematic cross-sectional view taken along line X1-X1′ of FIG. 1;

FIG. 3 is a plan view of the display device according to the embodiment;

FIG. 4 is an enlarged plan view of area A1 of FIG. 3;

FIG. 5 is an enlarged plan view of area A1 of FIG. 3;

FIG. 6 is a schematic cross-sectional view taken along line X2-X2′ of FIGS. 4 and 5;

FIG. 7 is an enlarged schematic cross-sectional view of area A2 of FIG. 6;

FIG. 8 is an enlarged schematic cross-sectional view of area A3 of FIG. 6;

FIG. 9 is a plan view illustrating the schematic arrangement of a dummy layer and a first color filter of a color filter member included in a color filter part of the display device according to the embodiment;

FIG. 10 is a plan view illustrating the schematic arrangement of the dummy layer and a second color filter of the color filter member included in the color filter part of the display device according to the embodiment;

FIG. 11 is a plan view illustrating the schematic arrangement of the dummy layer and a third color filter of the color filter member included in the color filter part of the display device according to the embodiment;

FIG. 12 is a schematic diagram of an equivalent circuit of a pixel of the display device according to the embodiment;

FIG. 13 is a plan view of area A1 of FIG. 3 including a light emitting part and a dummy layer included in the display device of FIG. 3;

FIG. 14 is a plan view of area A1 of FIG. 3 including a light emitting part and a dummy layer included in the display device of FIG. 3;

FIG. 15 is a plan view of area A1 of FIG. 3 including a light emitting part and a dummy layer included in the display device of FIG. 3;

FIGS. 16 through 24 are schematic process cross-sectional views for explaining a method of fabricating a display device according to an embodiment;

FIG. 25 is an enlarged schematic cross-sectional view of area A2 of FIG. 6 according to an embodiment;

FIG. 26 is a schematic diagram for explaining the effect of preventing lateral leakage current between adjacent pixels by a dummy layer in a display device according to an embodiment;

FIG. 27 is a chromaticity distribution schematic diagram; and

FIG. 28 illustrates a peak value for each wavelength of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, specific embodiments will be described with reference to the accompanying drawings.

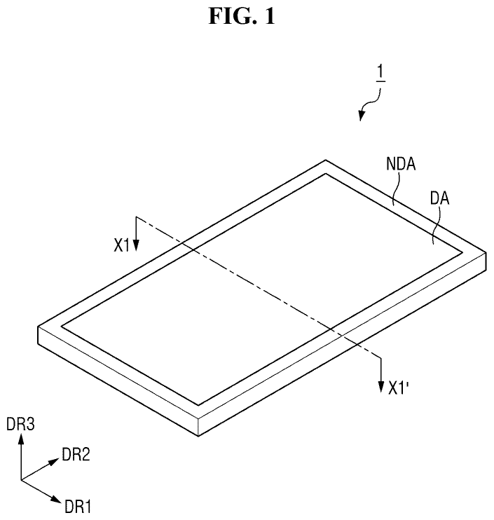

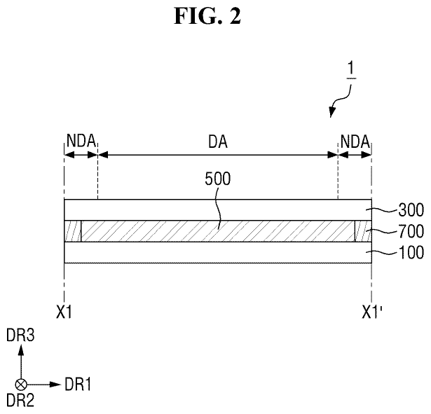

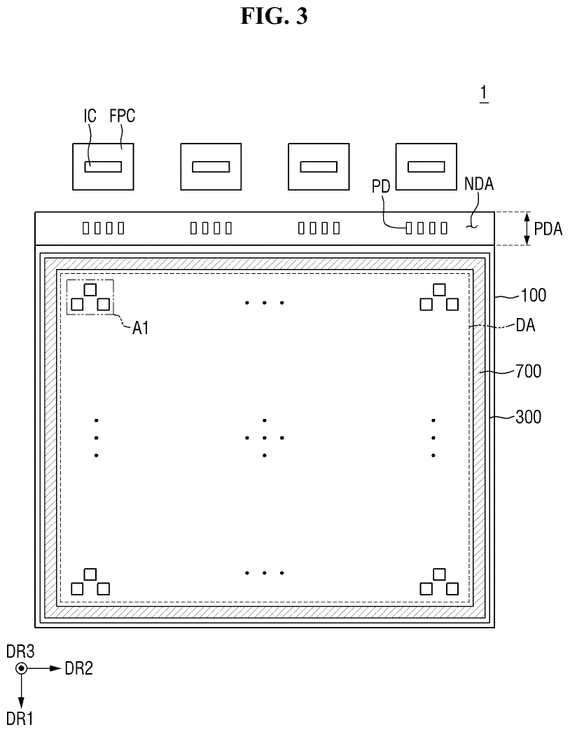

FIG. 1 is a perspective view of a display device 1 according to an embodiment. FIG. 2 is a schematic cross-sectional view taken along line X1-X1′ of FIG. 1. FIG. 3 is a plan view of the display device 1 according to the embodiment.

Referring to FIGS. 1 and 2, the display device 1 according to the embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). As another example, the display device 1 according to the embodiment may be applied as a display part of a television, a laptop computer, a monitor, a billboard, or an Internet of things (IoT) device. However, these are presented only as examples, and the display device 1 according to the embodiment may also be employed in other electronic devices as long as not departing from the spirit of the disclosure.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a vertical direction in the drawing, the second direction DR2 refers to a horizontal direction in the drawing, and the third direction DR3 refers to an up-down direction in the drawing, for example, a thickness direction. In the following specification, unless otherwise specified, a “direction” may refer to both directions extending to both sides in the direction. In case that it is desirable to distinguish both “directions” extending to both sides, a side will be referred to as a “first side in the direction,” and another side will be referred to as a “second side in the direction.” Based on FIG. 1, a direction in which an arrow is directed will be referred to as the first side, and a direction opposite to the direction will be referred to as the second side.

For ease of description, in referring to surfaces of the display device 1 or each member constituting the display device 1, one surface facing the first side in a direction in which an image may be displayed, for example, in the third direction DR3 will be referred to as an upper surface, and another surface opposite the one surface will be referred to as a lower surface. However, the disclosure is not limited thereto, and the one surface and another surface of each member may also be referred to as a front surface and a rear surface or as a first surface and a second surface, respectively. In describing relative positions of the members of the display device 1, the first side in the third direction DR3 may be referred to as an upper side, and the second side in the third direction DR3 may be referred to as a lower side.

The display device 1 may have a three-dimensional (3D) shape. For example, the display device 1 may have a rectangular parallelepiped shape or a 3D shape similar to the rectangular parallelepiped shape. In some embodiments, the display device 1 according to the embodiment may have a planar shape similar to a quadrilateral. In other words, the display device 1 according to the embodiment may have a planar shape similar to a quadrilateral having short sides in the first direction DR1 and long sides in the second direction DR2 as illustrated in FIG. 1. However, the disclosure is not limited thereto. For example, in the planar shape of the display device 1 according to the embodiment, each corner where a short side extending in the first direction DR1 meets a long side extending in the second direction DR2 may be rounded with a curvature (e.g., predetermined or selectable curvature) or may be right-angled. The planar shape of the display device 1 may not be limited to a quadrilateral shape but may also be similar to other polygonal shapes, a circular shape, or an oval shape.

The display device 1 may include a display area DA in which a screen may be displayed and a non-display area NDA in which a screen may not be displayed. In some embodiments, the non-display area NDA may surround edges of the display area DA, but the disclosure is not limited thereto. An image displayed in the display area DA may be viewed by a user from the first side in the third direction DR3 based on FIG. 1.

As illustrated in FIG. 2, the display device 1 may include a light emitting part 100 and a color filter part 300 facing the light emitting part 100 and may further include a sealing member 700 bonding the light emitting part 100 and the color filter part 300 together and a filler 500 filling a space between the light emitting part 100 and the color filter part 300.

The light emitting part 100 may include elements and circuits for displaying an image, for example, a pixel circuit such as a switching element, a pixel defining layer 170 in the display area DA, the pixel defining layer 170 defining a light emitting area and a non-light emitting area which will be described later, and a self-light emitting element. In an embodiment, the self-light emitting element may include at least one of an organic light emitting diode, a quantum dot light emitting diode, an inorganic material-based micro light emitting diode (e.g., micro LED), and an inorganic material-based nano light emitting diode (e.g., nano LED). For ease of description, a case where the self-light emitting element is an organic light emitting diode will be described below as an example. The light emitting part 100 may include a light transmitting member (e.g., a first light transmitting member TPL, a second light transmitting member WCL1, and a third light transmitting member WCL2) for converting the color of incident light emitted from the above self-light emitting element and irradiated to the color filter part 300. In some embodiments, the light transmitting member may include at least any one of wavelength conversion shifters and light scatterers as will be described later.

The color filter part 300 may be located on the light emitting part 100 and may face the light emitting part 100. In some embodiments, the color filter part 300 may include a color conversion pattern for converting the color of incident light provided from the light emitting part 100. In some embodiments, the color filter part 300 may include a color filter member 320, which will be described later, as the color conversion pattern.

The sealing member 700 may be located between the light emitting part 100 and the color filter part 300 in the non-display area NDA. The sealing member 700 may be disposed along edges of the light emitting part 100 and the color filter part 300 in the non-display area NDA to surround the display area DA in a plan view. The light emitting part 100 and the color filter part 300 may be bonded to each other by the sealing member 700.

In some embodiments, the sealing member 700 may be made of an organic material. For example, the sealing member 700 may be made of, but not limited to, epoxy resin. In some embodiments, the sealing member 700 may be applied in the form of a frit including glass or the like.

The filler 500 may be located in the space disposed between the light emitting part 100 and the color filter part 300 and may be surrounded by the sealing member 700. The filler 500 may fill the space between the light emitting part 100 and the color filter part 300.

In some embodiments, the filler 500 may be made of a material that can transmit light. In some embodiments, the filler 500 may be made of an organic material. For example, the filler 500 may be made of a silicon-based organic material, an epoxy-based organic material, or a mixture of a silicon-based organic material and an epoxy-based organic material.

FIG. 3 is a plan view of the display device 1 according to the embodiment.

Referring to FIG. 3, the display device 1 may further include flexible circuit boards FPC and driving chips IC.

The non-display area NDA of the display device 1 may include a pad area PDA, and multiple connection pads PD may be located in the pad area PDA. The pad area PDA may be defined on the light emitting part 100. Accordingly, the connection pads PD may be disposed on the light emitting part 100.

The flexible circuit boards FPC may be electrically connected to the connection pads PD. The flexible circuit boards FPC may electrically connect the light emitting part 100 to a circuit board that may provide signals and power for driving the display device 1.

The driving chips IC may be electrically connected to the circuit board to receive data and signals. In some embodiments, the driving chips IC may be data driving chips IC and may receive a data control signal and image data from the circuit board and generate and output data voltages corresponding to the image data.

In some embodiments, the driving chips IC may be mounted on the flexible circuit boards FPC. For example, the driving chips IC may be mounted on the flexible circuit boards FPC in the form of chips on films (COF).

The data voltages provided from the driving chips IC, the power provided from the circuit board, etc. may be transmitted to pixel circuits of the light emitting part 100 via the flexible circuit boards FPC and the connection pads PD as will be described later.

Multiple light emitting areas defined in the light emitting part 100 of the display device 1 and multiple light transmitting areas defined in the color filter part 300 will now be described in more detail.

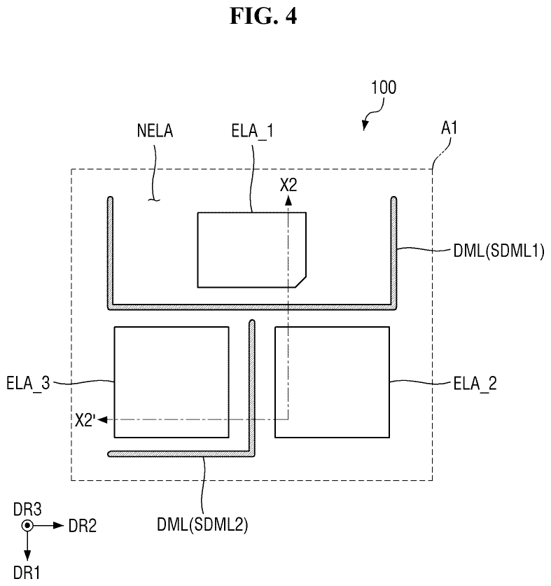

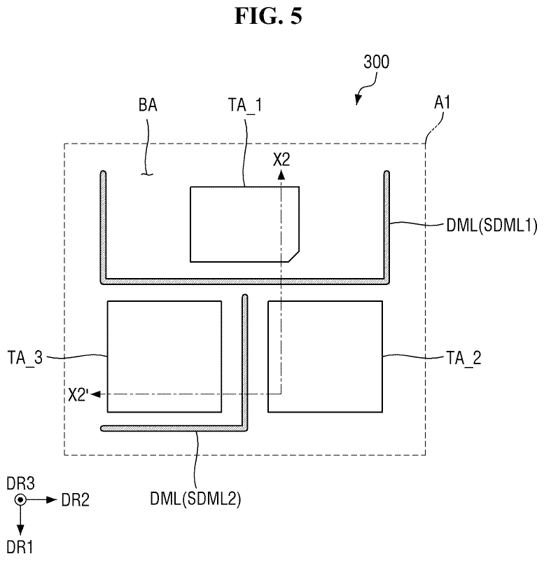

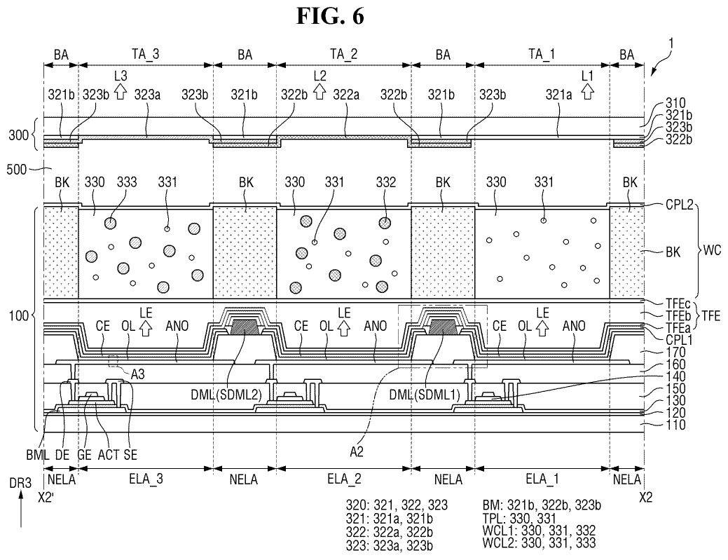

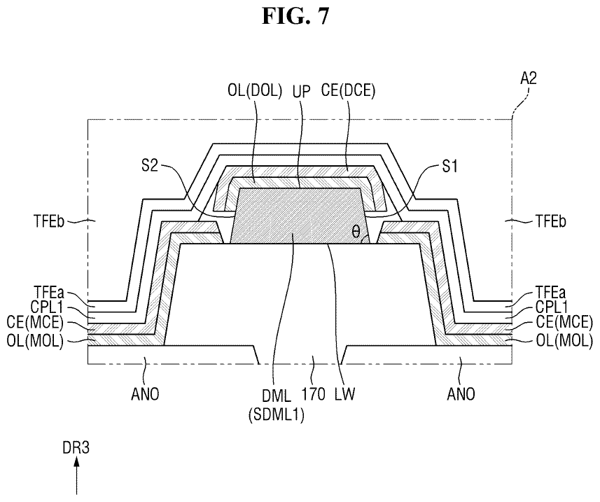

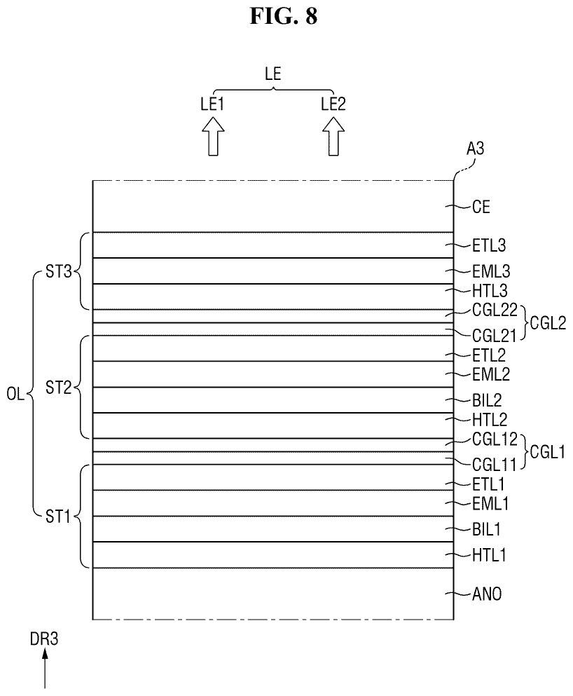

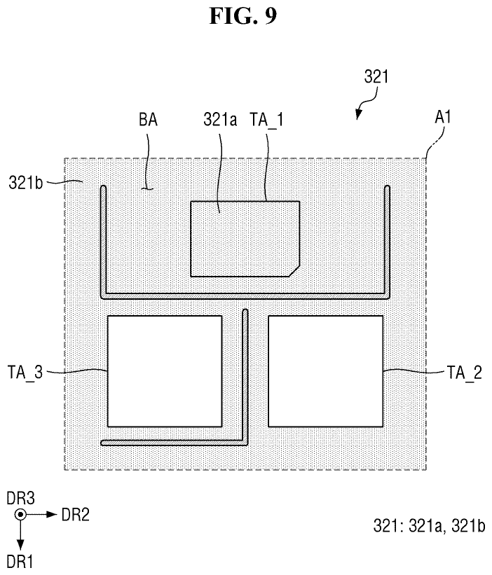

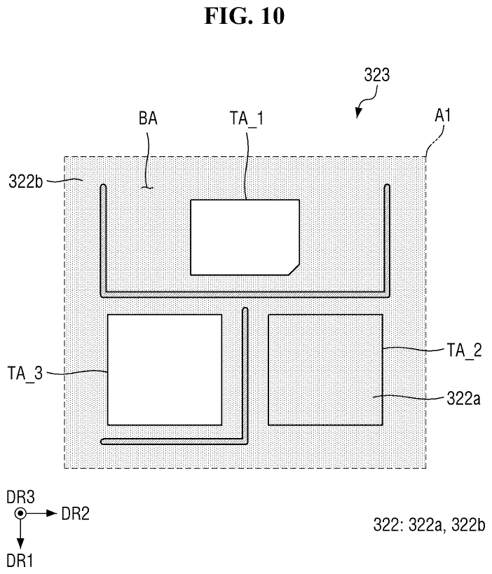

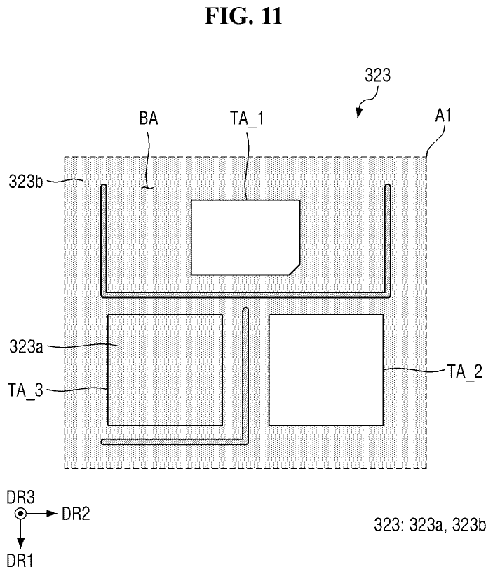

FIG. 4 is an enlarged plan view of area A1 of FIG. 3, more specifically, may be a schematic plan view of the light emitting part 100 and a dummy layer DML included in the display device 1 of FIG. 3. FIG. 5 is an enlarged plan view of area A1 of FIG. 3, more specifically, a schematic plan view of a light transmitting part and the dummy layer DML included in the display device 1 of FIG. 3. FIG. 6 is a schematic cross-sectional view taken along line X2-X2′ of FIGS. 4 and 5. FIG. 7 is an enlarged schematic cross-sectional view of area A2 of FIG. 6. FIG. 8 is an enlarged schematic cross-sectional view of area A3 of FIG. 6. FIG. 9 is a plan view illustrating the schematic arrangement of a first color filter 321 of the color filter member 320 included in the light transmitting part of the display device 1 according to the embodiment and the dummy layer DML. FIG. 10 is a plan view illustrating the schematic arrangement of a second color filter 322 of the color filter member 320 included in the light transmitting part of the display device 1 according to the embodiment and the dummy layer DML. FIG. 11 is a plan view illustrating the schematic arrangement of a third color filter 323 of the color filter member 320 included in the light transmitting part of the display device 1 according to the embodiment and the dummy layer DML.

Referring to FIGS. 4 through 6 in addition to FIG. 3, multiple light emitting areas may be defined in the light emitting part 100 of the display device 1 according to the embodiment, and multiple light transmitting areas may be defined in the color filter part 300.

The display area DA and the non-display area NDA defined in the display device 1 may be applied to the light emitting part 100 and the color filter part 300.

A first light emitting area ELA_1, a second light emitting area ELA_2, and a third light emitting area ELA_3 may be defined in the display area DA of the light emitting part 100 as illustrated in FIG. 4. The first light emitting area ELA_1, the second light emitting area ELA_2, and the third light emitting area ELA_3 may be areas where light generated by light emitting elements of the light emitting part 100 may be emitted to the outside of the light emitting part 100. A non-light emitting area NELA may be an area where light may not be emitted to the outside of the light emitting part 100. In some embodiments, the non-light emitting area NELA may surround the first light emitting area ELA_1, the second light emitting area ELA_2, and the third light emitting area ELA_3 in the display area DA, but the disclosure is limited thereto.

In some embodiments, light emitted from the first light emitting area ELA_1, the second light emitting area ELA_2 and the third light emitting area ELA_3 to the outside may be light of a first color. In some embodiments, the light of the first color may be blue light and may have a peak wavelength in a range of about 440 to about 480 nm. Here, the peak wavelength refers to a wavelength at which the intensity of light may be a maximum.

In some embodiments, as illustrated in FIG. 4, the third light emitting area ELA_3 and the second light emitting area ELA_2 may be sequentially located in the second direction DR2. The first light emitting area ELA_1 may be located on a side of a space between the third light emitting area ELA_3 and the second light emitting area ELA_2. The first light emitting area ELA_1, the second light emitting area ELA_2, and the third light emitting area ELA_3 may form a group.

As illustrated in FIG. 3, a group formed by the first light emitting area ELA_1, the second light emitting area ELA_2, and the third light emitting area ELA_3 may be repeatedly disposed in the first direction DR1 and the second direction DR2 in the display area DA. However, the disclosure is not limited thereto. For example, the arrangement of the first light emitting area ELA_1, the second light emitting area ELA_2, and the third light emitting area ELA_3 can be changed variously. Therefore, the first light emitting area ELA_1, the second light emitting area ELA_2, and the third light emitting area ELA_3 may also be sequentially located in the second direction DR2. For ease of description, a case where the first light emitting area ELA_1, the second light emitting area ELA_2, and the third light emitting area ELA_3 may be arranged as illustrated in FIG. 4 will be described below as an example.

In some embodiments, the area of the first light emitting area ELA_1, the area of the second light emitting area ELA_2, and the area of the third light emitting area ELA_3 may be substantially the same. However, the disclosure is not limited thereto. For example, the area of the first light emitting area ELA_1, the area of the second light emitting area ELA_2, and the area of the third light emitting area ELA_3 may also be different from each other. In some embodiments, the first light emitting area ELA_1, the second light emitting area ELA_2, and the third light emitting area ELA_3 may have a polygonal planar shape, but the disclosure is not limited thereto. For ease of description, an example in which the second light emitting area ELA_2 and the third light emitting area ELA_3 have a quadrilateral planar shape and have substantially a same area, and the first light emitting area ELA_1 has a pentagonal planar shape and has a smaller area than the second light emitting area ELA_2 (or the third light emitting area ELA_3) will be described below.

A first light transmitting area TA_1, a second light transmitting area TA_2, and a third light transmitting area TA_3 may be defined in the display area DA of the color filter part 300. The first light emitting area TA_1, the second light transmitting area TA_2, and the third light emitting area TA_3 may be areas through which light generated from the first light emitting area ELA_1, the second light emitting area ELA_2, and the third light emitting area ELA_3 of the light emitting part 100 may be transmitted. A light blocking area BA may be located around the first light transmitting area TA_1, the second light transmitting area TA_2, and the third light transmitting area TA_3 in the display area DA of the color filter part 300. In some embodiments, the light blocking area BA may surround the first light transmitting area TA_1, the second light transmitting area TA_2, and the third light transmitting area TA_3. However, the disclosure is not limited thereto. For example, the light blocking area BA may be located in the non-display area NDA as well as in the display area DA of the color filter part 300.

The first light transmitting area TA_1 may correspond to and overlap the first light emitting area ELA_1, the second light transmitting area TA_2 may correspond to and overlap the second light emitting area ELA_2, and the third light transmitting area TA_3 may correspond to and overlap the third light emitting area ELA_3. In some embodiments, the first light transmitting area TA_1 may have substantially the same area as the first light emitting area ELA_1 and completely overlap the first light emitting area ELA_1, the second light transmitting area TA_2 may have substantially the same area as the second light emitting area ELA_2 and completely overlap the second light emitting area ELA_2, and the third light transmitting area TA_3 may have substantially the same area as the third light emitting area ELA_3 and completely overlap the third light emitting area ELA_3. However, the disclosure is not limited thereto. For example, the first light emitting area TA_1 may also have a different area from the first light emitting area ELA_1, the second light transmitting area TA_2 may also have a different area from the second light emitting area ELA_2, and the third light transmitting area TA_3 may also have a different area from the third light emitting area ELA_3. For ease of description, a case where the first light transmitting area TA_1 has substantially the same area as the first light emitting area ELA_1 and completely overlaps the first light emitting area ELA_1, the second light transmitting area TA_2 has substantially the same area as the second light emitting area ELA_2 and completely overlaps the second light emitting area ELA_2, and the third light transmitting area TA_3 has substantially the same area as the third light emitting area ELA_3 and completely overlaps the third light emitting area ELA_3 will be described below.

Accordingly, the third light transmitting area TA_3 and the second light transmitting area TA_2 may be sequentially located in the second direction DR2. The first light transmitting area TA_1 may be located on a side of a space between the third light transmitting area TA_3 and the second light transmitting area TA_2. The first light transmitting area TA_1, the second light transmitting area TA_2, and the third light transmitting area TA_3 may form a group. As illustrated in FIG. 3, a group formed by the first light transmitting area TA_1, the second light transmitting area TA_2, and the third light transmitting area TA_3 may be repeatedly disposed in the first direction DR1 and the second direction DR2 in the display area DA.

As described above, light of the first color emitted from the light emitting part 100 may be provided to the outside of the display device 1 through the first light transmitting area TA_1, the second light transmitting area TA_2, and the third light transmitting area TA_3. Light output from the first light transmitting area TA_1 to the outside of the display device 1 may be referred to as first output light, light output from the second light transmitting area TA_2 to the outside of the display device 1 may be referred to as second output light, and light output from the third light transmitting area TA_3 to the outside of the display device 1 may be referred to as third output light. The first output light may be light of the first color, the second output light may be light of a second color, and the third output light may be light of a third color.

In some embodiments, the light of the first color may be blue light having a peak wavelength in a range of about 440 to about 480 nm as described above, and the light of the second color may be green light having a peak wavelength in a range of about 510 to about 550 nm. The light of the third color may be red light having a peak wavelength in a range of about 610 to about 650 nm.

In a plan view as illustrated in FIG. 4, the dummy layer DML may be disposed in the non-light emitting area NELA. In some embodiments, the dummy layer DML may be disposed in a boundary portion between the first through third light emitting areas ELA_1 through ELA_3 that form a group. For example, the dummy layer DML may include a first sub-dummy layer SDML1 and a second sub-dummy layer SDML2. The first sub-dummy layer SDML1 may be disposed between the first light emitting area ELA_1 and the second light emitting area ELA_2 and between the first light emitting area ELA_1 and the third light emitting area ELA_3. The second sub-dummy layer SDML2 may be disposed between the second light emitting area ELA_2 and the third light emitting area ELA_3. According to an embodiment, the dummy layer DML may have a line shape in a plan view.

According to some embodiments, the first sub-dummy layer SDML1 may have a U shape surrounding all but a surface of the first light emitting area ELA_1, and the second sub-dummy layer SDML2 may have an L shape (e.g., an L shape inverted by 180 degrees with respect to the first direction DR1) facing two adjacent surfaces of the third light emitting area ELA_3. Here, at least a portion of the U-shaped first sub-dummy layer SDML1 may be disposed between the first light emitting area ELA_1 and the second light emitting area ELA_2 and between the first light emitting area ELA_1 and the third light emitting area ELA_3 as described above. At least a portion of the inverted L-shaped second sub-dummy layer SDML2 may be disposed between the second light emitting area ELA_2 and the third light emitting area ELA_3 as described above.

In a plan view as illustrated in FIG. 5, the above-described dummy layer DML may be disposed in the light blocking area BA. In some embodiments, the dummy layer DML may be disposed in a boundary portion between the first through third light transmitting areas TA_1 through TA_3 that form a group. For example, as described above, the dummy layer DML may include the first sub-dummy layer SDML1 and the second sub-dummy layer SDML2. The first sub-dummy layer SDML1 may be disposed between the first light transmitting area TA_1 and the second light transmitting area TA_2 and between the first light transmitting area TA_1 and the third light transmitting area TA_3. The second sub-dummy layer SDML2 may be disposed between the second light transmitting area TA_2 and the third light transmitting area TA_3.

According to some embodiments, the first sub-dummy layer SDML1 may have a U-shape surrounding all but a surface of the first light transmitting area TA_1, and the second sub-dummy layer SDML2 may have an L shape (e.g., an L shape inverted by 180 degrees with respect to the first direction DR1) facing two adjacent surfaces of the third light transmitting area TA_3. Here, at least a portion of the U-shaped first sub-dummy layer SDML1 may be disposed between the first light transmitting area TA_1 and the second light transmitting area TA_2 and between the first light transmitting area TA_1 and the third light transmitting area TA_3 as described above. At least a portion of the inverted L-shaped second sub-dummy layer SDML2 may be disposed between the second light transmitting area TA_2 and the third light transmitting area TA_3 as described above.

The structure of the display device 1 will now be described in detail.

Referring to FIG. 6, as described above, the display device 1 may include the light emitting part 100, the color filter part 300 disposed on the light emitting part 100 to face the light emitting part 100, and the filler 500 disposed between the light emitting part 100 and the color filter part 300. For ease of description, the light emitting part 100, the color filter part 300, and the filler 500 will be described below in this order.

The light emitting part 100 may have a structure in which a first substrate 110, a buffer layer 120, bottom metal layers BML, a first insulating layer 130, semiconductor layers ACT, gate electrodes GE, gate insulating layers 140, a second insulating layer 150, source/drain electrodes, a third insulating layer 160, light emitting elements, a pixel defining layer 170, the dummy layer DML, a first capping layer CPL1, a thin-film encapsulation layer TFE, and a wavelength conversion member WC may be sequentially stacked on each other to the first side in the third direction DR3.

The first substrate 110 of the light emitting part 100 may serve as a base of the light emitting part 100. The first substrate 110 may be made of a light transmitting material. The first substrate 110 may be a glass substrate or a plastic substrate. In case that the first substrate 110 is a plastic substrate, it may have flexibility. In some embodiments, in case that the first substrate 110 is a plastic substrate, it may include, but is not limited to, polyimide.

The buffer layer 120 of the light emitting part 100 may be disposed on the first substrate 110. The buffer layer 120 may block foreign material or moisture introduced through the first substrate 110 from entering elements disposed on the buffer layer 120.

In some embodiments, the buffer layer 120 may include an inorganic material such as SiO₂, SiNₓ, SiON, or a combination thereof, and may be formed as a single layer or a multilayer, but the disclosure is not limited thereto.

The bottom metal layers BML of the light emitting part 100 may be disposed on the buffer layer 120. The bottom metal layers BML may block external light or light emitted from the light emitting elements to be described later from entering the semiconductor layers ACT. Accordingly, it may be possible to prevent leakage current from being generated by light in thin-film transistors which will be described later or may reduce the generation of the leakage current.

The bottom metal layers BML may be made of a material that blocks light and has conductivity. In some embodiments, the bottom metal layers BML may include a single material selected from metals such as silver (Ag), nickel (Ni), gold (Au), platinum (Pt), aluminum (Al), copper (Cu), molybdenum (Mo), titanium (Ti), neodymium (Nd), an alloy of the metals, or a combination thereof. In some embodiments, the bottom metal layers BML may have a single-layer structure or a multilayer structure. For example, in case that the bottom metal layers BML have a multilayer structure, each of the bottom metal layers BML may be, but is not limited to, a stacked structure of titanium (Ti)/copper (Cu)/indium tin oxide (ITO) or a stacked structure of titanium (Ti)/copper (Cu)/aluminum oxide (Al₂O₃).

In some embodiments, the bottom metal layers BML may correspond to the semiconductor layers ACT and overlap the semiconductor layers ACT, respectively. In some embodiments, the bottom metal layers BML may be wider than the semiconductor layers ACT.

In some embodiments, the bottom metal layers BML may be part of data lines, power supply lines, and lines that electrically connect thin-film transistors not illustrated in the drawing to the thin-film transistors (GE, ACT, DE and SE in FIG. 6) illustrated in the drawing. In some embodiments, the bottom metal layers BML may be made of a material having a smaller resistance than source electrodes SE and drain electrodes DE.

The first insulating layer 130 of the light emitting part 100 may be disposed on the bottom metal layers BML. The first insulating layer 130 may electrically insulate the bottom metal layers BML from the semiconductor layers ACT. The first insulating layer 130 may cover the bottom metal layers BML.

In some embodiments, the first insulating layer 130 may include, but may not be limited to, an inorganic material such as SiO₂, SiNₓ, SiON, Al₂O₃, TiO₂, Ta₂O, HfO₂, ZrO₂, or a combination thereof.

The semiconductor layers ACT of the light emitting part 100 may be disposed on the first insulating layer 130. The semiconductor layers ACT may respectively correspond to the first light emitting area ELA_1, the second light emitting area ELA_2, and the third light emitting area ELA_3 in the display area DA of the light emitting part 100. The semiconductor layers ACT may overlap the bottom metal layers BML, respectively. Accordingly, generation of photocurrent in the semiconductor layers ACT can be suppressed.

The semiconductor layers ACT may include an oxide semiconductor. In some embodiments, each of the semiconductor layers ACT may be made of a Zn oxide-based material such as Zn oxide, In—Zn oxide or Ga—In—Zn oxide or may be an In—Ga—Zn—O (IGZO) semiconductor containing metals such as indium (In) and gallium (Ga) in ZnO. However, the disclosure is not limited thereto. For example, the semiconductor layers ACT may also include amorphous silicon or polysilicon.

The gate electrodes GE of the light emitting part 100 may be disposed on the semiconductor layers ACT. The gate electrodes GE may overlap the semiconductor layers ACT in the display area DA. In some embodiments, the gate electrodes GE may be narrower than the semiconductor layers ACT, but the disclosure is not limited thereto.

In some embodiments, in consideration of adhesion to an adjacent layer, surface flatness of a layer on which it is stacked on each other, and workability, each of the gate electrodes GE may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu) and may be formed as a single layer or a multilayer, but the disclosure is not limited thereto.

The gate insulating layers 140 of the light emitting part 100 may be disposed between the semiconductor layers ACT and the gate electrodes GE. The gate insulating layers 140 may insulate the semiconductor layers ACT from the gate electrodes GE. In some embodiments, the gate insulating layers 140 may have a partially patterned shape instead of being formed as a layer on a surface of the first substrate 110 on the first side in the third direction DR3. The gate insulating layers 140 may be narrower than the semiconductor layers ACT and may be wider than the gate electrodes GE, but the disclosure is not limited thereto.

In some embodiments, the gate insulating layers 140 may include an inorganic material. For example, the gate insulating layers 140 may include one of the inorganic materials exemplified in the description of the first insulating layer 130.

The second insulating layer 150 of the light emitting part 100 may be disposed on the gate insulating layers 140 to cover the semiconductor layers ACT and the gate electrodes GE. In some embodiments, the second insulating layer 150 may function as a planarization layer that may provide an approximately flat surface.

The second insulating layer 150 may include an organic material. In some embodiments, the second insulating layer 150 may include, but is not limited to, at least any one of photo acryl (PAC), polystyrene, polymethyl methacrylate (PMMA), polyacrylonitrile (PAN), polyamide, polyimide, polyarylether, heterocyclic polymer, parylene, fluorine-based polymer, epoxy resin, benzocyclobutene series resin, siloxane series resin, silane resin, or a combination thereof.

The source electrodes SE and the drain electrodes DE of the light emitting part 100 may be spaced apart from each other on the second insulating layer 150. The source electrodes SE and the drain electrodes DE may be electrically connected to the semiconductor layers ACT respectively through contact holes penetrating the second insulating layer 150. In some embodiments, the source electrodes SE may penetrate the first insulating layer 130 as well as the second insulating layer 150 and thus may be electrically connected to the bottom metal layers BML. In case that the bottom metal layers BML are part of lines that transmit signals or voltages, the source electrodes SE may be electrically connected and electrically coupled to the bottom metal layers BML to receive voltages provided to the lines. For example, in case that the bottom metal layers BML are floating patterns rather than lines, voltages provided to the source electrodes SE may be transmitted to the bottom metal layers BML.

Each of the source electrodes SE and the drain electrodes DE may include aluminum (Al), copper (Cu), titanium (Ti), the like, or a combination thereof, and may be formed as a multilayer or a single layer. In some embodiments, the source electrodes SE and the drain electrodes DE may have, but are not limited to, a multilayer structure of Ti/Al/Ti.

The semiconductor layers ACT, the gate electrodes GE, the source electrodes SE, and the drain electrodes DE described above may form thin-film transistors which may be switching elements. In some embodiments, the thin-film transistors may be located in the first light emitting area ELA_1, the second light emitting area ELA_2, and the third light emitting area ELA_3, respectively. In some embodiments, a portion of each of the thin-film transistors may be located in the non-light emitting area NELA.

The third insulating layer 160 of the light emitting part 100 may be disposed on the second insulating layer 150 to cover the thin-film transistors. In some embodiments, the third insulating layer 160 may be a planarization layer.

The third insulating layer 160 may be made of an organic material. In some embodiments, the third insulating layer 160 may include acrylic resin, epoxy resin, imide resin, ester resin, or a combination thereof or may include a photosensitive organic material, but the disclosure is not limited thereto.

Anodes ANO (or first electrodes) may be located on the third insulating layer 160 in the display area DA of the light emitting part 100.

The anodes ANO may overlap the first light emitting area ELA_1, the second light emitting area ELA_2 and the third light emitting area ELA_3, respectively, and at least a portion of each of the anodes ANO may extend to the non-light emitting area NELA. The anodes ANO may be electrically connected to the drain electrodes DE of the thin-film transistors.

In some embodiments, the anodes ANO may be reflective electrodes. Each of the anodes ANO may be a metal layer including a metal such as Ag, Mg, Al, Pt, Pd, Au, Ni, Nd, Ir, Cr, or a combination thereof. In an embodiment, each of the anodes ANO may further include a metal oxide layer stacked on the metal layer. In an embodiment, the anodes ANO may have a multilayer structure, for example, a two-layer structure of ITO/Ag, Ag/ITO, ITO/Mg or ITO/MgF or a three-layer structure of ITO/Ag/ITO.

The pixel defining layer 170 of the light emitting part 100 may be disposed on the anodes ANO. The pixel defining layer 170 may define the first light emitting area ELA_1, the second light emitting area ELA_2, and the third light emitting area ELA_3 as openings that expose the anodes ANO.

The pixel defining layer 170 may overlap the light blocking area BA of the color filter member 320 in the third direction DR3 and will be described later. The pixel defining layer 170 may overlap a bank member BK in the third direction DR3 and will be described later.

In some embodiments, the pixel defining layer 170 may include an organic insulating material such as polyacrylates resin, epoxy resin, phenolic resin, polyamides resin, polyimides resin, unsaturated polyesters resin, polyphenylenethers resin, polyphenylenesulfides resin, benzocyclobutene (BCB), or a combination thereof. However, the disclosure is not limited thereto.

The dummy layer DML of the light emitting part 100 may be disposed on the pixel defining layer 170 as illustrated in FIGS. 6 and 7. The dummy layer DML may overlap the pixel defining layer 170 and contact the pixel defining layer 170. The dummy layer DML may be disposed on an uppermost surface of the pixel defining layer 170. For example, the dummy layer DML may be disposed at a highest part of the pixel defining layer 170. Here, a height of the pixel defining layer 170 may refer to, for example, a distance from an upper surface of the substrate 110 to an upper surface of the pixel defining layer 170 in the third direction DR3.

The dummy layer DML may overlap two anodes ANO adjacent to each other. For example, as illustrated in FIG. 6, a side of the dummy layer DML may overlap the anode ANO of the first light emitting area ELA_1, and another side of the dummy layer DML may overlap the anode ANO of the second light emitting area ELA_2 adjacent to the first light emitting area ELA_1.

An angle (hereinafter, referred to as a taper angle θ) between a lower surface LW of the dummy layer DML and a side surface (e.g., S1) adjacent to the lower surface LW may be an acute angle. For example, the taper angle θ of the dummy layer DML may be in a range of about 65 to about 90 degrees. In other words, the taper angle θ between the lower surface LW of the dummy layer DML and a first side surface S1 of the dummy layer DML may be in a range of about 65 to about 90 degrees, and a taper angle between the lower surface LW of the dummy layer DML and a second side surface S2 of the dummy layer DML may be in a range of about 65 to about 90 degrees. According to an embodiment, the taper angle θ between the lower surface LW and the first side surface S1 of the dummy layer DML may be in a range of about 65 to about 80 degrees, and the taper angle between the lower surface LW and the second side surface S2 of the dummy layer DML may be in a range of about 65 to about 80 degrees.

The dummy layer DML may have a width that gradually decreases in a direction (e.g., the third direction DR3) from the lower surface LW of the dummy layer DML toward an upper surface UP of the dummy layer DML. In other words, the dummy layer DML may have a width that gradually decreases in a thickness direction of the dummy layer DML in the third direction DR3. For example, the dummy layer DML may have a trapezoidal cross section.

The lower surface LW of the dummy layer DML may contact the upper surface of the pixel defining layer 170, and the upper surface UP of the dummy layer DML may contact a light emitting layer OL (e.g., a dummy light emitting layer to be described later). The upper surface UP of the dummy layer DML may face the lower surface LW of the dummy layer DML in the third direction DR3. In other words, the upper surface UP of the dummy layer DML may be disposed opposite the lower surface LW of the dummy layer DML in the third direction DR3. The first side surface S1 and the second side surface S2 of the dummy layer DML may be symmetrical by about 180 degrees with respect to the third direction DR3.

The dummy layer DML may have a thickness of, for example in a range of about 1000 to about 8000 Å. Here, the thickness of the dummy layer DML may be the size of the dummy layer DML in the third direction DR3. According to an embodiment, the dummy layer DML may have a thickness in a range of about 1000 to about 4000 Å. According to an embodiment, the dummy layer DML may have a thickness in a range of about 3000 to about 8000 Å.

The dummy layer DML may be made of a material including an inorganic material. For example, the dummy layer DML may include an inorganic material that can be deposited at a temperature of about 360° C. or lower. According to an embodiment, the dummy layer DML may be made of a material including at least one of SiNₓ, SiOₓ, and SiON.

In some embodiments, the dummy layer DML may have a specific color. For example, the dummy layer DML may have a yellowish color. In an embodiment for this purpose, the dummy layer DML may be made of a material including SiNₓ. For example, the dummy layer DML may include silicon-rich SiNₓ. Here, a flow rate (sccm) ratio between SiH₄ gas and NH₃ gas used to form the dummy layer DML may be 4:1 or higher. As a specific example, a flow rate of SiH₄ gas may be four or more times a flow rate of NH₃ gas. The dummy layer DML fabricated in such an environment may have a yellowish color.

The light emitting layer OL of the light emitting part 100 may be disposed on the anodes ANO. In some embodiments, the light emitting layer OL may be in the shape of a layer formed over the light emitting areas ELA_1 through ELA_3 and the non-light emitting area NELA. In some embodiments, the light emitting layer OL may be located only in the display area DA. However, the disclosure is not limited thereto. For example, a portion of the light emitting layer OL may be further disposed in the non-display area NDA. For example, the light emitting layer OL may be further disposed on the pixel defining layer 170 and the dummy layer DML.

In some embodiments, a portion of the light emitting layer OL may be broken. For example, at least a portion of the light emitting layer OL may be broken around the dummy layer DML. Accordingly, the light emitting layer OL may be divided into a light emitting layer portion (hereinafter, referred to as a main light emitting layer MOL) continuously disposed on the anodes ANO and the pixel defining layer 170 and a light emitting layer portion (hereinafter, referred to as a dummy light emitting layer DOL) disposed on the dummy layer DML. For example, the main light emitting layer MOL on the anodes ANO and the dummy light emitting layer DOL on the dummy layer DML may be physically separated (or electrically disconnected) from each other. This may be due to the dummy layer DML between the pixel defining layer 170 and the light emitting layer OL. For example, since the taper angle θ of the dummy layer DML may be fairly large (e.g., in a range of about 65 to about 80 degrees) as described above, the light emitting layer OL may be separated around the dummy layer DML into the main light emitting layer MOL and the dummy light emitting layer DOL. According to an embodiment, while the main light emitting layer MOL may be electrically connected to the anodes ANO, the dummy light emitting layer DOL may not be electrically connected to the anodes ANO. Therefore, a voltage of the anodes ANO may not be applied to the dummy light emitting layer DOL.

Since at least a portion of the light emitting layer OL may be broken around the dummy layer DML as described above, a large resistance may be generated in a current path between pixels disposed adjacent to each other with the dummy layer DML disposed between them. Accordingly, lateral leakage current between the adjacent pixels can be minimized.

According to some embodiments, a portion of the main light emitting layer MOL which may be adjacent to the dummy layer DML may be disposed on the pixel defining layer 170.

The light emitting layer OL will be described in more detail later.

A cathode CE (or a second electrode) of the light emitting part 100 may be disposed on the light emitting layer OL. In some embodiments, the cathode CE may be disposed on the light emitting layer OL and may be in the shape of a layer formed over the light emitting areas ELA_1 through ELA_3 and the non-light emitting area NELA. In other words, the cathode CE may completely cover the light emitting layer OL.

In some embodiments, a portion of the cathode CE may be broken. For example, at least a portion of the cathode CE may be broken around the dummy layer DML. Accordingly, the cathode CE may be divided into a cathode portion (hereinafter, referred to as a main cathode MCE) disposed on the main light emitting layer MOL to overlap the anodes ANO described above and a cathode portion (hereinafter, referred to as a dummy cathode DCE) disposed on the dummy light emitting layer DOL to overlap the dummy layer DML described above. For example, the main cathode MCE on the main light emitting layer MOL and the dummy cathode DCE on the dummy light emitting layer DOL may be physically separated from each other. This may be due to the dummy layer DML having a large taper angle between the pixel defining layer 170 and the light emitting layer OL. According to an embodiment, while the main cathode MCE may be electrically connected to a second voltage line which will be described later, the dummy cathode DCE may not be electrically connected to the second voltage line. Therefore, a second voltage may not be applied to the dummy cathode DCE. Here, the second voltage line may be disposed, for example, under the cathode CE. The main cathode MCE may be electrically connected to the second voltage line thereunder through a laser drilling hole (a type of contact hole) that penetrates an insulating layer.

The cathode CE may have translucency or transparency. In case that a thickness of the cathode CE is tens to hundreds of angstroms (Å), the cathode CE may have translucency. In some embodiments, in case that the cathode CE has translucency, it may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). The cathode CE may also have transparency by including a transparent conductive oxide. In some embodiments, in case that the cathode CE has transparency, it may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or a combination thereof.

The anodes ANO, the light emitting layer OL, and the cathode CE may form light emitting elements. For example, the anode ANO, the light emitting layer OL and the cathode CE overlapping the first light emitting area ELA_1 may form a first light emitting element, the anode ANO, the light emitting layer OL and the cathode CE overlapping the second light emitting area ELA_2 may form a second light emitting element, and the anode ANO, the light emitting layer OL and the cathode CE overlapping the third light emitting area ELA_3 may form a third light emitting element. Each of the first light emitting element, the second light emitting element, and the third light emitting element may emit output light LE.

Referring to FIG. 8, the output light LE finally emitted from the light emitting layer OL (e.g., the main light emitting layer MOL) may be a mixture of a first component LE1 and a second component LE2. Each of the first component LE1 and the second component LE2 in the output light LE may have a peak wavelength in a range of about 440 to less than about 480 nm. For example, the output light LE may be blue light.

In some embodiments, the light emitting layer OL may have a structure in which multiple light emitting material layers overlap, for example, a tandem structure as illustrated in FIG. 8. In other words, the light emitting layer OL including the main light emitting layer MOL and the dummy light emitting layer DOL may have the tandem structure described above. For example, the light emitting layer OL may include a first stack ST1 including a first light emitting material layer EML1, a second stack ST2 located on the first stack ST1 and including a second light emitting material layer EML2, a third stack ST3 located on the second stack ST2 and including a third light emitting material layer EML3, a first charge generation layer CGL1 located between the first stack ST1 and the second stack ST2, and a second charge generation layer CGL2 located between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other.

In some embodiments, the first light emitting material layer EML1, the second light emitting material layer EML2, and the third light emitting material layer EML3 may all emit light of the first color, for example, blue light. For example, each of the first light emitting material layer EML1, the second light emitting material layer EML2, and the third light emitting material layer EML3 may be a blue light emitting layer and may include an organic material.

In some embodiments, at least any one of the first light emitting material layer EML1, the second light emitting material layer EML2 and the third light emitting material layer EML3 may emit first blue light having a first peak wavelength, and at least another one of the first light emitting material layer EML1, the second light emitting material layer EML2 and the third light emitting material layer EML3 may emit second blue light having a second peak wavelength different from the first peak wavelength. For example, any one of the first light emitting material layer EML1, the second light emitting material layer EML2 and the third light emitting material layer EML3 may emit the first blue light having the first peak wavelength, and another two of the first light emitting material layer EML1, the second light emitting material layer EML2 and the third light emitting material layer EML3 may emit the second blue light having the second peak wavelength. For example, the output light LE finally emitted from the light emitting layer OL may be a mixture of the first component LE1 and the second component LE2. Here, the first component LE1 may be the first blue light having the first peak wavelength, and the second component LE2 may be the second blue light having the second peak wavelength.

In some embodiments, any one of the first peak wavelength and the second peak wavelength may be in a range of about 440 to less than about 460 nm. Another one of the first peak wavelength and the second peak wavelength may be in a range of about 460 to about 480 nm. However, the range of the first peak wavelength and the range of the second peak wavelength are not limited to this example. For example, both the range of the first peak wavelength and the range of the second peak wavelength may include about 460 nm. In some embodiments, any one of the first blue light and the second blue light may be light of a deep blue color, and another one of the first blue light and the second blue light may be light of a sky blue color.

According to some embodiments, the output light LE emitted from the light emitting layer OL may be blue light and may include a long wavelength component and a short wavelength component. Therefore, the light emitting layer OL may finally (or ultimately) emit blue light having a broader emission peak as the output light LE, thereby improving color visibility at a side viewing angle compared with a conventional light emitting element that emits blue light having a sharp emission peak.

In some embodiments, each of the first light emitting material layer EML1, the second light emitting material layer EML2, and the third light emitting material layer EML3 may include a host and a dopant. The host may not be particularly limited as long as it is a commonly used material. However, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (I), 4,4′,4″-tris(29 midazole-9-yl)-triphenylamine (TCTA), 1,3,5-tris(N-phenylbenzimidazole-2-yl)benzene (TPBi), 3-tert-butyl-9,10-di(29 midazo-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene) (MADN) may be used.

Each of the first light emitting material layer EML1, the second light emitting material layer EML2, and the third light emitting material layer EML3 which emit blue light may include, for example, a fluorescent material including any one of spiro-DPVBi, spiro-6P, distyryl-benzene (DSB), distyryl-arylene (DSA), a polyfluorene (PFO)-based polymer, a poly (p-phenylene vinylene) (PPV)-based polymer, or a combination thereof. For another example, a phosphorescent material including an organometallic complex such as (4,6-F2ppy)2Irpic may be included.

As described above, at least one of the first light emitting material layer EML1, the second light emitting material layer EML2 and the third light emitting material layer EML3 and at least another one of the first light emitting material layer EML1, the second light emitting material layer EML2 and the third light emitting material layer EML3 emit blue light in different wavelength ranges. To emit blue light in different wavelength ranges, the first light emitting material layer EML1, the second light emitting material layer EML2 and the third light emitting material layer EML3 may include a same material, and a resonance distance may be adjusted. As another example, to emit blue light in different wavelength ranges, at least one of the first light emitting material layer EML1, the second light emitting material layer EML2 and the third light emitting material layer EML3 and at least another one of the first light emitting material layer EML1, the second light emitting material layer EML2 and the third light emitting material layer EML3 may include different materials.

However, the disclosure is not limited thereto. The first light emitting material layer EML1, the second light emitting material layer EML2 and the third light emitting material layer EML3 may also all emit blue light having a peak wavelength in a range of about 440 to about 480 nm and may be made of a same material.

Blue light emitted from the first light emitting material layer EML1, the second light emitting material layer EML2 and the third light emitting material layer EML3 may also all have a peak wavelength in a range of about 440 to about 480 nm, and the first light emitting material layer EML1, the second light emitting material layer EML2 and the third light emitting material layer EML3 may be made of a same material.

As another example, in an embodiment, at least any one of the first light emitting material layer EML1, the second light emitting material layer EML2 and the third light emitting material layer EML3 may emit the first blue light having the first peak wavelength, another one of the first light emitting material layer EML1, the second light emitting material layer EML2 and the third light emitting material layer EML3 may emit the second blue light having the second peak wavelength different from the first peak wavelength, and another one of the first light emitting material layer EML1, the second light emitting material layer EML2 and the third light emitting material layer EML3 may emit third blue light having a third peak wavelength different from the first peak wavelength and the second peak wavelength. In some embodiments, any one of the first peak wavelength, the second peak wavelength and the third peak wavelength may be in a range of about 440 to less than about 460 nm. Another one of the first peak wavelength, the second peak wavelength and the third peak wavelength may be in a range of about 460 to less than about 470 nm, and another one of the first peak wavelength, the second peak wavelength and the third peak wavelength may be in a range of about 470 to about 480 nm.

According to some embodiments, the output light LE emitted from the light emitting layer OL may be blue light and may include a long wavelength component, a medium wavelength component and a short wavelength component. Therefore, the light emitting layer OL may finally emit blue light having a broader emission peak as the output light LE and improve color visibility at a side viewing angle.

According to the above-described embodiments, it may be possible to improve light efficiency and extend the life of the display device 1 as compared with a conventional light emitting element that does not employ a tandem structure, for example, a structure in which multiple light emitting material layers are stacked on each other.

As another example, in some embodiments, at least any one of the first light emitting material layer EML1, the second light emitting material layer EML2 and the third light emitting material layer EML3 may emit light of the first color, for example, blue light, and at least another one of the first light emitting material layer EML1, the second light emitting material layer EML2 and the third light emitting material layer EML3 may emit light of the second color, for example, green light. In some embodiments, blue light emitted from at least any one of the first light emitting material layer EML1, the second light emitting material layer EML2, and the third light emitting material layer EML3 may have a peak wavelength in a range of about 440 to about 480 nm or in a range of about 460 to about 480 nm. Green light emitted from at least another one of the first light emitting material layer EML1, the second light emitting material layer EML2, and the third light emitting material layer EML3 may have a peak wavelength in a range of about 510 to about 550 nm.

For example, any one of the first light emitting material layer EML1, the second light emitting material layer EML2 and the third light emitting material layer EML3 may be a green light emitting layer OL (or a green light emitting material layer) emitting green light, and another two of the first light emitting material layer EML1, the second light emitting material layer EML2 and the third light emitting material layer EML3 may be blue light emitting layers OL (or blue light emitting material layers) emitting blue light. In case that another two of the first light emitting material layer EML1, the second light emitting material layer EML2 and the third light emitting material layer EML3 are blue light emitting layers OL (or blue light emitting material layers), peak wavelengths of blue light emitted from the two blue light emitting layers OL (the two blue light emitting material layers) may be in the same range or in different ranges.

According to some embodiments, the output light LE emitted from the light emitting layer OL may be a mixture of the first component LE1 which may be blue light and the second component LE2 which may be green light. For example, in case that the first component LE1 is dark blue light and the second component LE2 is green light, the output light LE may be light having a sky blue color. As in the above-described embodiments, the output light LE emitted from the light emitting layer OL may be a mixture of blue light and green light and may include a long wavelength component and a short wavelength component. Therefore, the light emitting layer OL may finally emit blue light having a broader emission peak as the output light LE and improve color visibility at a side viewing angle. Since the second component LE2 of the output light LE may be green light, a green light component can be supplemented in the light provided from the display device 1 to the outside. Accordingly, the color reproducibility of the display device 1 can be improved.

In some embodiments, a green light emitting material layer among the first light emitting material layer EML1, the second light emitting material layer EML2, and the third light emitting material layer EML3 may include a host and a dopant. The host included in the green light emitting material layer may not be particularly limited as long as it may be a commonly used material. However, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (I), 4,4′,4″-tris(33 midazole-9-yl)-triphenylamine (TCTA), 1,3,5-tris(N-phenylbenzimidazole-2-yl)benzene (TPBi), 3-tert-butyl-9,10-di(33 midazo-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene) (MADN), or a combination thereof may be used.

The dopant included in the green light emitting material layer may be, for example, a fluorescent material including tris-(8-hydroyquinolato) aluminum(III) (Alq3) or may be a phosphorescent material such as Ir(ppy)3(fac tris(2-phenylpyridine)iridium), Ir(ppy)2(acac)(Bis(2-phenylpyridine)(acetylacetonate)iridium(III)), Ir(mpyp)3(2-phenyl-4-methyl-pyridine iridium), or a combination thereof.

The first charge generation layer CGL1 may be located between the first stack ST1 and the second stack ST2. The first charge generation layer CGL1 may inject electric charges into each light emitting layer OL (or each light emitting material layer). The first charge generation layer CGL1 may control the charge balance between the first stack ST1 and the second stack ST2. The first charge generation layer CGL1 may include an n-type charge generation layer CGL11 and a p-type charge generation layer CGL12. The p-type charge generation layer CGL12 may be disposed on the n-type charge generation layer CGL11 and may be located between the n-type charge generation layer CGL11 and the second stack ST2.

The first charge generation layer CGL1 may have a structure in which the n-type charge generation layer CGL11 and the p-type charge generation layer CGL12 may be in contact with each other. The n-type charge generation layer CGL11 may be disposed closer to an anode ANO among the anode ANO and the cathode CE. The p-type charge generation layer CGL12 may be disposed closer to the cathode CE among the anode ANO and the cathode CE. The n-type charge generation layer CGL11 supplies electrons to the first light emitting material layer EML1 adjacent to the anode ANO, and the p-type charge generation layer CGL12 supplies holes to the second light emitting material layer EML2 included in the second stack ST2. Since the first charge generation layer CGL1 may be disposed between the first stack ST1 and the second stack ST2 to provide electric charges to each light emitting layer OL (or each light emitting material layer), luminous efficiency can be improved, and a driving voltage can be lowered.

In FIG. 6, the anode ANO corresponding to the first light emitting area ELA_1 may be defined as a first anode, the anode ANO corresponding to the second light emitting area ELA_2 may be defined as a second anode, and the anode ANO corresponding to the third light emitting area ELA_3 may be defined as a third anode. The first stack ST1 may be located on the first anode, the second anode, and the third anode. Here, the first stack ST1 may further include a first hole transport layer HTL1, a first electron blocking layer BIL1, and a first electron transport layer ETL1.

The first hole transport layer HTL1 may be located on the first anode, the second anode, and the third anode. The first hole transport layer HTL1 may facilitate the transportation of holes and may include a hole transport material. The hole transport material may include, but is not limited to, a carbazole derivative such as N-phenylcarbazole or polyvinylcarbazole, a fluorene derivative; a triphenylamine derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA); N,N′-di(1-naphthyl)-N,N′-diphenylbenzidine) (NPB), 4,4′-Cyclohexylidene bis[N,N-bis(4-methylphenyl)benzenamine](TAPC), or a combination thereof.

The first electron blocking layer BIL1 may be located on the first hole transport layer HTL1 and may be located between the first hole transport layer HTL1 and the first light emitting material layer EML1. The first electron blocking layer BIL1 may include a hole transport material and a metal or a metal compound in order to prevent electrons generated by the first light emitting material layer EML1 from entering the first hole transport layer HTL1. In some embodiments, the first hole transport layer HTL1 and the first electron blocking layer BIL1 described above may be formed as a single layer in which their respective materials may be mixed.

The first electron transport layer ETL1 may be located on the first light emitting material layer EML1 and may be located between the first charge generation layer CGL1 and the first light emitting material layer EML1. In some embodiments, the first electron transport layer ETL1 may include an electron transport material such as tris-(8-hydroxyquinolinato)aluminum (Alq3), 1,3,5-tri(1-phenyl-1H-benzo[d]midazole-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (Balq), berylliumbis(benzoquinolin-10-olate) (Bebq2), 9,10-di(naphalene-2-yl)anthracene (I), or a mixture thereof. However, the disclosure is not limited to the type of the electron transport material. The second stack ST2 may be located on the first charge generation layer CGL1 and may further include a second hole transport layer HTL2, a second electron blocking layer BIL2 and a second electron transport layer ETL2.

The second hole transport layer HTL2 may be located on the first charge generation layer CGL1. The second hole transport layer HTL2 may be made of the same material as the first hole transport layer HTL1 or may include one or more materials selected from the materials exemplified as the materials included in the first hole transport layer HTL1. The second hole transport layer HTL2 may be composed of a single layer or multiple layers.

The second electron blocking layer BIL2 may be located on the second hole transport layer HTL2 and may be located between the second hole transport layer HTL2 and the second light emitting material layer EML2. The second electron blocking layer BIL2 may have the same material and structure as the first electron blocking layer BIL1 or may include one or more materials selected from the materials exemplified as the materials included in the first electron blocking layer BIL1.

The second electron transport layer ETL2 may be located on the second light emitting material layer EML2 and may be located between the second charge generation layer CGL2 and the second light emitting material layer EML2. The second electron transport layer ETL2 may have the same material and structure as the first electron transport layer ETL1 or may include one or more materials selected from the materials exemplified as the materials included in the first electron transport layer ETL1. The second electron transport layer ETL2 may be composed of a single layer or multiple layers.

The second charge generation layer CGL2 may be located on the second stack ST2 and may be located between the second stack ST2 and the third stack ST3.

The second charge generation layer CGL2 may have the same structure as the first charge generation layer CGL1 described above. For example, the second charge generation layer CGL2 may include an n-type charge generation layer CGL21 disposed closer to the second stack ST2 and a p-type charge generation layer CGL22 disposed closer to the cathode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 may be in contact with each other. The first charge generation layer CGL1 and the second charge generation layer CGL2 may be made of different materials or a same material.

The third stack ST3 may be located on the second charge generation layer CGL2 and may further include a third hole transport layer HTL3 and a third electron transport layer ETL3.

The third hole transport layer HTL3 may be located on the second charge generation layer CGL2. The third hole transport layer HTL3 may be made of the same material as the first hole transport layer HTL1 or may include one or more materials selected from the materials exemplified as the materials included in the first hole transport layer HTL1. The third hole transport layer HTL3 may be composed of a single layer or multiple layers. In case that the third hole transport layer HTL3 is composed of multiple layers, the layers may include different materials.

The third electron transport layer ETL3 may be located on the third light emitting material layer EML3 and may be located between the cathode CE and the third light emitting material layer EML3. The third electron transport layer ETL3 may have the same material and structure as the first electron transport layer ETL1 or may include one or more materials selected from the materials exemplified as the materials included in the first electron transport layer ETL1. The third electron transport layer ETL3 may be composed of a single layer or multiple layers. In case that the third electron transport layer ETL3 is composed of multiple layers, the layers may include different materials.

Although not illustrated in the drawing, a hole injection layer may be further located in at least any one of the spaces between the first stack ST1 and the first anode, the second anode and the third anode, between the second stack ST2 and the first charge generation layer CGL1, and between the third stack ST3 and the second charge generation layer CGL2. The hole injection layer may facilitate the injection of holes into the first light emitting material layer EML1, the second light emitting material layer EML2 and the third light emitting material layer EML3. In some embodiments, the hole injection layer may be made of, but not limited to, any one or more of copper phthalocyanine (CuPc), poly(3,4-ethylenedioxythiphene) (PEDOT), polyaniline (PANI), and N,N-dinaphthyl-N,N′-diphenyl benzidine (NPD). In some embodiments, the hole injection layer may be located between the first stack ST1 and the first anode, the second anode and the third anode, between the second stack ST2 and the first charge generation layer CGL1, and between the third stack ST3 and the second charge generation layer CGL2.

Although not illustrated in the drawing, an electron injection layer may be further located in at least any one of the spaces between the third electron transport layer ETL3 and the cathode CE, between the second charge generation layer CGL2 and the second stack ST2, and between the first charge generation layer CGL1 and the first stack ST1. The electron injection layer may facilitate the injection of electrons and may use tris(8-hydroxyquinolino)aluminum) (Alq3), PBD, TAZ, spiro-PBD, Balq or Salq, but the disclosure is not limited thereto. The electron injection layer may be a metal halide compound, for example, any one or more of MgF₂, LiF, NaF, KF, RbF, CsF, FrF, LiI, NaI, KI, RbI, CsI, FrI and CaF₂, but the disclosure is not limited thereto. The electron injection layer may also include a lanthanum material such as Yb, Sm, or Eu. As another example, the electron injection layer may include both a metal halide material and a lanthanum material such as RbI:Yb or KI:Yb. In case that the electron injection layer includes both a metal halide material and a lanthanum material, the electron injection layer may be formed by co-deposition of the metal halide material and the lanthanum material. In some embodiments, the electron injection layer may be located between the third electron transport layer ETL3 and the cathode CE, between the second charge generation layer CGL2 and the second stack ST2, and between the first charge generation layer CGL1 and the first stack ST1.

In some embodiments, the light emitting layer OL may not include a red light emitting material layer and thus may not emit light of the third color, for example, red light. In other words, the output light LE may not include a light component having a peak wavelength in a range of about 610 to about 650 nm and may include only a light component having a peak wavelength in a range of about 440 to about 550 nm.

According to an embodiment, the light emitting layer OL may be broken by the dummy layer DML. This may mean that at least one layer included in the light emitting layer OL, for example, the first hole transport layer HTL1, the first electron blocking layer BIL1, the first light emitting material layer EML1, the first electron transport layer ETL1, the n-type charge generation layer CGL11, the p-type charge generation layer CGL12, the second hole transport layer HTL2, the second electron blocking layer BIL2, the second light emitting material layer EML2, the second electron transport layer ETL2, the n-type charge generation layer CGL21, the p-type charge generation layer CGL22, the third hole transport layer HTL3, the third light emitting material layer EML3 and the third electron transport layer ETL3 may all be broken.

According to an embodiment, the main light emitting layer MOL may include the first hole transport layer HTL1, the first electron blocking layer BIL1, the first light emitting material layer EML1, the first electron transport layer ETL1, the n-type charge generation layer CGL11, the p-type charge generation layer CGL12, the second hole transport layer HTL2, the second electron blocking layer BIL2, the second light emitting material layer EML2, the second electron transport layer ETL2, the n-type charge generation layer CGL21, the p-type charge generation layer CGL22, the third hole transport layer HTL3, the third light emitting material layer EML3, and the third electron transport layer ETL3 described above.

According to an embodiment, the dummy light emitting layer DOL may include the first hole transport layer HTL1, the first electron blocking layer BIL1, the first light emitting material layer EML1, the first electron transport layer ETL1, the n-type charge generation layer CGL11, the p-type charge generation layer CGL12, the second hole transport layer HTL2, the second electron blocking layer BIL2, the second light emitting material layer EML2, the second electron transport layer ETL2, the n-type charge generation layer CGL21, the p-type charge generation layer CGL22, the third hole transport layer HTL3, the third light emitting material layer EML3, and the third electron transport layer ETL3 described above.

Referring back to FIG. 6, the first capping layer CPL1 may be disposed on the cathode CE. The first capping layer CPL1 may improve viewing angle characteristics and increase external light emission efficiency. The first capping layer CPL1 may be commonly disposed in the first light emitting area ELA_1, the second light emitting area ELA_2, the third light emitting area ELA_3, and the non-light emitting area NELA. The first capping layer CPL1 may completely cover the cathode CE.

The first capping layer CPL1 may include at least any one of an inorganic material and an organic material having light transmitting properties. In other words, the first capping layer CPL1 may be made of an inorganic layer or an organic layer or may be made of an organic layer including inorganic particles. In some embodiments, the first capping layer CPL1 may include, but is not limited to, a triamine derivative, a carbazole biphenyl derivative, an arylenediamine derivative, an aluminum quinolium complex (Alq3), or a combination thereof.

In some embodiments, the first capping layer CPL1 may be disposed on the cathode CE to overlap the dummy layer DML described above. The first capping layer CPL1 may not be broken. Accordingly, the first capping layer CPL1 may cover broken portions of the light emitting layer OL and/or broken portions of the cathode CE.

The thin-film encapsulation layer TFE of the light emitting part 100 may be disposed on the first capping layer CPL1. The thin-film encapsulation layer TFE may protect elements located under the thin-film encapsulation layer TFE from external foreign substances such as moisture. The thin-film encapsulation layer TFE may be commonly disposed in the first light emitting area ELA_1, the second light emitting area ELA_2, the third light emitting area ELA_3 and the non-light emitting area NELA. The thin-film encapsulation layer TFE may completely cover the first capping layer CPL1.

The thin-film encapsulation layer TFE may include a lower inorganic layer TFEa, an organic layer TFEb, and an upper inorganic layer TFEc sequentially stacked on each other on the first capping layer CPL1.

The lower inorganic layer TFEa may completely cover the first capping layer CPL1 in the display area DA to cover the first light emitting element, the second light emitting element and the third light emitting element.

The organic layer TFEb may be disposed on the lower inorganic layer TFEa to cover the first light emitting element, the second light emitting element and the third light emitting element.

The upper inorganic layer TFEc may be disposed on the organic layer TFEb to completely cover the organic layer TFEb.

In some embodiments, each of the lower inorganic layer TFEa and the upper inorganic layer TFEc may be made of, but not limited to, silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, or a combination thereof.

In some embodiments, the organic layer TFEb may be made of, but not limited to, acrylic resin, methacrylic resin, polyisoprene, vinyl resin, epoxy resin, urethane resin, cellulose resin, perylene resin), or a combination thereof.

In some embodiments, the thin-film encapsulation layer TFE may be disposed on the first capping layer CPL1 to overlap the dummy layer DML described above. The thin-film encapsulation layer TFE may not be broken. Accordingly, the thin-film encapsulation layer TFE may cover broken portions of the light emitting layer OL and/or broken portions of the cathode CE.

The wavelength conversion member WC of the light emitting part 100 may be disposed on the thin-film encapsulation layer TFE. The wavelength conversion member WC may emit red light, green light, and blue light by converting the wavelength of light emitted from the light emitting element layer EML.

The wavelength conversion member WC may include a first wavelength conversion layer TPL, a second wavelength conversion layer WCL1, a third wavelength conversion layer WCL2, the bank member BK, and a second capping layer CPL2.

The bank member BK may define spaces in which wavelength conversion layers to be described later may be disposed. The bank member BK may surround the first wavelength conversion layer TPL, the second wavelength conversion layer WCL1, and the third wavelength conversion layer WCL2 in a plan view. The bank member BK may overlap the non-light emitting area NELA of the light emitting part 100 and the light blocking area BA of the color filter part 300. The bank member BK may not overlap the light emitting areas ELA_1 through ELA_3 of the light emitting part 100 and the light transmitting areas TA_1 through TA_3 of the color filter part 300.

In some embodiments, the bank member BK may include, but is not limited to, a photocurable organic material or a photocurable organic material including a light blocking material.

The wavelength conversion member WC of the light emitting part 100 may include the first wavelength conversion layer TPL overlapping the first light transmitting area TA_1, the second wavelength conversion layer WCL1 overlapping the second light transmitting area TA_2, and the third wavelength conversion layer WCL2 overlapping the third light transmitting area TA_3.

The first wavelength conversion layer TPL may be disposed in a space defined by the bank member BK and may overlap the first light emitting area ELA_1 and the first light transmitting area TA_1 in the third direction DR3. The first wavelength conversion layer TPL may contact (e.g., directly contact) the second capping layer CPL2 and the bank member BK.

The first wavelength conversion layer TPL may be a light transmitting pattern that transmits incident light. Specifically, the output light LE provided by the first light emitting element may be blue light as described above and may pass through the first wavelength conversion layer TPL and a first filtering pattern area 321a of the first color filter 321 to exit the display device 1. In other words, first output light L1 emitted from the first light emitting area ELA_1 to the outside through the first light transmitting area TA_1 may be blue light.

The first wavelength conversion layer TPL may include a base resin 330 and light scatterers 331.

The base resin 330 may be made of an organic material having high light transmittance. In some embodiments, the base resin 330 may include, but is not limited to, an organic material such as epoxy resin, acrylic resin, cardo resin, imide resin, or a combination thereof.

The light scatterers 331 may have a refractive index different from that of the base resin 330 and may form an optical interface with the base resin 330. The light scatterers 331 may be light scattering particles. The light scatterers 331 may scatter incident light in random directions regardless of the incident direction of the incident light without substantially converting the wavelength of the incident light passing through the light transmitting area TA_-1.

The light scatterers 331 may be materials that scatter at least a portion of transmitted light and may include metal oxide particles or organic particles. In some embodiments, the light scatterers 331 may include titanium oxide (TiO₂), zirconium oxide (ZrO₂), aluminum oxide (Al₂O₃), indium oxide (In₂O₃), zinc oxide (ZnO), tin oxide (SnO₂)), or a combination thereof as the metal oxide and may include acrylic resin or urethane resin as the organic particles, but the disclosure is not limited thereto.

The second wavelength conversion layer WCL1 may be disposed in a space defined by the bank member BK and may overlap the second light emitting area ELA_2 and the second light transmitting area TA_2 in the third direction DR3. The second wavelength conversion layer WCL1 may contact (e.g., directly contact) the second capping layer CPL2 and the bank member BK.

The second wavelength conversion layer WCL1 may be a wavelength converting pattern that converts or shifts a peak wavelength of incident light into another specific peak wavelength and outputs light having the specific peak wavelength. Specifically, the output light LE provided by the second light emitting element may be blue light as described above and may be converted into green light having a peak wavelength in a range of about 510 to about 550 nm as it passes through the second wavelength conversion layer WCL1 and a second filtering pattern area 322a of the second color filter 322. Accordingly, the green light may be emitted to the outside of the display device 1. In other words, second output light L2 emitted from the second light emitting area ELA_2 to the outside through the second light transmitting area TA_2 may be green light.

The second wavelength conversion layer WCL1 may include a base resin 330, light scatterers 331 dispersed in the base resin 330, and first wavelength shifters 332 dispersed in the base resin 330.

The first wavelength shifters 332 may convert or shift a peak wavelength of incident light into another specific peak wavelength. The first wavelength shifters 332 may convert the output light LE, which may be blue light provided by the second light emitting element, into green light having a single peak wavelength in a range of about 510 to about 550 nm and output the green light.

In some embodiments, the first wavelength shifters 332 may be, but are not limited to, quantum dots, quantum rods, or phosphors. For ease of description, a case where the first wavelength shifters 332 may be quantum dots will be described below. The quantum dots may be particulate materials that emit light of a specific color in case that electrons transit from a conduction band to a valence band. The quantum dots may be semiconductor nanocrystalline materials. The quantum dots may have a specific band gap according to their composition and size. Thus, the quantum dots may absorb light and emit light having a unique wavelength. Examples of semiconductor nanocrystals of the quantum dots include group IV nanocrystals, group II-VI compound nanocrystals, group III-V compound nanocrystals, group IV-VI nanocrystals, and combinations thereof.

The group II-VI compounds may be selected from binary compounds selected from CdSe, CdTe, ZnS, ZnSe, ZnTe, ZnO, HgS, HgSe, HgTe, MgSe, MgS and mixtures thereof; ternary compounds selected from InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and quaternary compounds selected from HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compounds may be selected from binary compounds selected from GaN, GaP, GaAs, GaSb, AlN, AlP, AlAs, AlSb, InN, InP, InAs, InSb and mixtures thereof; ternary compounds selected from GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and mixtures thereof; and quaternary compounds selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

The group IV-VI compounds may be selected from binary compounds selected from SnS, SnSe, SnTe, PbS, PbSe, PbTe and mixtures thereof; ternary compounds selected from SnSeS, SnSeTe, SnSTe, PbSeS, PbSeTe, PbSTe, SnPbS, SnPbSe, SnPbTe and mixtures thereof; and quaternary compounds selected from SnPbSSe, SnPbSeTe, SnPbSTe and mixtures thereof. The group IV elements may be selected from silicon (Si), germanium (Ge), and a mixture thereof. The group IV compounds may be binary compounds selected from silicon carbide (SiC), silicon germanium (SiGe), and a mixture thereof.

Here, the binary, ternary or quaternary compounds may be present in particles at a uniform concentration or may be present in the same particles at partially different concentrations. They may have a core/shell structure in which a quantum dot surrounds another quantum dot. An interface between the core and the shell may have a concentration gradient in which the concentration of an element present in the shell may be reduced toward the center.

In some embodiments, the quantum dots may have a core-shell structure that may include a core containing the above-described nanocrystal and a shell surrounding the core. The shell of each quantum dot may serve as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of an element present in the shell may be reduced toward the center. The shell of each quantum dot may be, for example, a metal or non-metal oxide, a semiconductor compound, or a combination thereof.

For example, the metal or non-metal oxide may be, but is not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ or NiO or a ternary compound such as MgAl₂O₄, CoFe₂O₄, NiFe₂O₄, CoMn₂O₄, or a combination thereof.

The semiconductor compound may be, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

Light emitted from the first wavelength shifters 332 may have a full width of half maximum (FWHM) of an emission wavelength spectrum of about 45 nm or less, about 40 nm or less, or about 30 nm or less. Therefore, the color purity and color reproducibility of the display device 1 can be further improved. The light emitted from the first wavelength shifters 332 may be radiated in various directions regardless of the incident direction of incident light. Therefore, the lateral visibility of the second color displayed in the second light transmitting area TA_2 can be improved.

A portion of the output light LE provided by the second light emitting element may be transmitted through the second wavelength conversion layer WCL1 without being converted into green light by the first wavelength shifters 332. Of the output light LE, a component incident on the second filtering pattern area 322a of the second color filter 322 without being wavelength-converted by the second wavelength conversion layer WCL1 may be blocked by the second filtering pattern area 322a. On the other hand, green light into which the output light LE has been converted by the second wavelength conversion layer WCL1 may be transmitted through the second filtering pattern area 322a and emitted to the outside. For example, the second output light L2 emitted to the outside of the display device 1 through the second light transmitting area TA_2 may be green light.

The third wavelength conversion layer WCL2 may be disposed in a space defined by the bank member BK and may overlap the third light emitting area ELA_3 and the third light transmitting area TA_3 in the third direction DR3. The third wavelength conversion layer WCL2 may contact (e.g., directly contact) the second capping layer CPL2 and the bank member BK.

The third wavelength conversion layer WCL2 may be a wavelength converting pattern that converts or shifts a peak wavelength of incident light into another specific peak wavelength and outputs light having the specific peak wavelength. Specifically, the output light LE provided by the third light emitting element may be blue light as described above and may be converted into red light having a peak wavelength in a range of about 610 to about 650 nm as it passes through the third wavelength conversion layer WCL2 and a third filtering pattern area 323a of the third color filter 323. Accordingly, the red light may be emitted to the outside of the display device 1. In other words, third output light L3 emitted from the third light emitting area ELA_3 to the outside through the third light transmitting area TA_3 may be red light.

The third wavelength conversion layer WCL2 may include a base resin 330, light scatterers 331 dispersed in the base resin 330, and second wavelength shifters 333 dispersed in the base resin 330.

The second wavelength shifters 333 may convert or shift a peak wavelength of incident light to another specific peak wavelength. The second wavelength shifters 333 may convert the output light LE, which may be blue light provided by the third light emitting element, into red light having a single peak wavelength in a range of about 610 to about 650 nm and output the red light. In some embodiments, the second wavelength shifters 333 may be, but are not limited to, quantum dots, quantum rods, or phosphors. In case that the second wavelength shifters 333 are quantum dots, they may have substantially the same composition as the above-described first wavelength shifters 332 in case that the first wavelength shifters 332 are quantum dots. Therefore, a description of the second wavelength shifters 333 will be omitted.

A portion of the output light LE provided by the third light emitting element may be transmitted through the third wavelength conversion layer WCL2 without being converted into red light by the second wavelength shifters 333. Of the output light LE, a component incident on the third filtering pattern area 323a of the third color filter 323 without being wavelength-converted by the third wavelength conversion layer WCL2 may be blocked by the third filtering pattern area 323a. On the other hand, red light into which the output light LE has been converted by the third wavelength conversion layer WCL2 may be transmitted through the third filtering pattern area 323a and emitted to the outside. For example, the third output light L3 emitted to the outside of the display device 1 through the third light transmitting area TA_3 may be red light.

The color filter part 300 may be disposed on the wavelength conversion member WC of the light emitting part 100. The color filter part 300 may have a structure in which a second substrate 310 and the color filter member 320 may be sequentially stacked on each other to the second side in the third direction DR3.

The color filter part 300 will now be described in detail with reference to FIGS. 9 through 11 in addition to FIG. 6.

The second substrate 310 of the color filter part 300 may serve as a base of the color filter part 300. The second substrate 310 may be made of a light transmitting material. The second substrate 310 may be a glass substrate or a plastic substrate. In case that the second substrate 310 is a plastic substrate, it may have flexibility. In some embodiments, in case that the second substrate 310 is a plastic substrate, it may include, but is not limited to, polyimide. Since the light emitting part 100 and the color filter part 300 face each other in the third direction DR3 as described above, the first substrate 110 of the light emitting part 100 and the second substrate 310 of the color filter part 300 may face each other in the third direction DR3.

The color filter member 320 of the color filter part 300 may be disposed between the second substrate 310 and the filler 500. The color filter member 320 may include filtering pattern areas and a light blocking pattern portion BM. The light blocking pattern portion BM may surround the filtering pattern areas. The filtering patterns of the color filter member 320 may define light transmitting areas of the color filter part 300, and the light blocking pattern portion BM may define the light blocking area BA of the color filter part 300.

The color filter member 320 may include the first color filter 321, the second color filter 322, and the third color filter 323 as illustrated in FIGS. 6 and 9 through 11. The first color filter 321 may absorb both the second light and the third light except for the first light, the second color filter 322 may absorb both the first light and the third light except for the second light, and the third color filter 323 may absorb both the first light and the second light except for the third light. In other words, the first color filter 321 may transmit the first light, the second color filter 322 may transmit the second light, and the third color filter 323 may transmit the third light.

In some embodiments, the first color filter 321 may be a blue color filter and may include a blue colorant. As used herein, the term “colorant” is a concept encompassing both a dye and a pigment. The first color filter 321 may include a base resin, and the blue colorant may be dispersed in the base resin. In some embodiments, the second color filter 322 may be a green color filter and may include a green colorant. The second color filter 322 may include a base resin, and the green colorant may be dispersed in the base resin. In some embodiments, the third color filter 323 may be a red color filter and may include a red colorant. The third color filter 323 may include a base resin, and the red colorant may be dispersed in the base resin.

The first color filter 321 may include the first filtering pattern area 321a and a first light blocking pattern area 321b surrounding the first filtering pattern area 321a. The second color filter 322 may include the second filtering pattern area 322a and a second light blocking pattern area 322b surrounding the second filtering pattern area 322a. The third color filter 323 may include the third filtering pattern area 323a and a third light blocking pattern area 323b surrounding the third filtering pattern area 323a. Specifically, the first filtering pattern area 321a of the first color filter 321 may overlap the first light transmitting area TA_1, and the first light blocking pattern area 321b of the first color filter 321 may surround the first filtering pattern area 321a overlapping the first light transmitting area TA_1. However, the first light blocking pattern area 321b of the first color filter 321 may not overlap the second light transmitting area TA_2 and the third light transmitting area TA_3 but may overlap the light blocking area BA. The second filtering pattern area 322a of the second color filter 322 may overlap the second light transmitting area TA_2, and the second light blocking pattern area 322b of the second color filter 322 may surround the second filtering pattern area 322a overlapping the second light transmitting area TA_2. However, the second light blocking pattern area 322b of the second color filter 322 may not overlap the first light transmitting area TA_1 and the third light transmitting area TA_3 but may overlap the light blocking area BA. The third filtering pattern area 323a of the third color filter 323 may overlap the third light transmitting area TA_3, and the third light blocking pattern area 323b of the third color filter 323 may surround the third filtering pattern area 323a overlapping the third light transmitting area TA_3. However, the third light blocking pattern area 323b of the third color filter 323 may not overlap the first light transmitting area TA_1 and the second light transmitting area TA_2 but may overlap the light blocking area BA. In other words, the filtering pattern areas of the color filter member 320 may include the first filtering pattern area 321a of the first color filter 321, the second filtering pattern area 322a of the second color filter 322 and the third filtering pattern area 323a of the third color filter 323, and the light blocking pattern portion BM may have a structure in which the first light blocking pattern area 321b of the first color filter 321, the second light blocking pattern area 322b of the second color filter 322, and the third light blocking pattern area 323b of the third color filter 323 may be stacked on each other.

The first filtering pattern area 321a of the first color filter 321 may function as a blocking filter that blocks red light and green light. Specifically, the first filtering pattern area 321a may transmit the first light (e.g., blue light) and block or absorb the second light (e.g., green light) and the third light (e.g., red light).

The second filtering pattern area 322a of the second color filter 322 may function as a blocking filter that blocks blue light and red light. Specifically, the second filtering pattern area 322a may transmit the second light (e.g., green light) and block or absorb the first light (e.g., blue light) and the third light (e.g., red light).

The third filtering pattern area 323a of the third color filter 323 may function as a blocking filter that blocks blue light and green light. Specifically, the third filtering pattern area 323a may transmit the third light (e.g., red light) and block or absorb the first light (e.g., blue light) and the second light (e.g., green light).

In some embodiments, the light blocking pattern portion BM may have a structure in which the first light blocking pattern area 321b, the third light blocking pattern area 323b, and the second light blocking pattern area 322b may be sequentially stacked on each other in the third direction DR3. However, the disclosure is not limited thereto. For example, the light blocking pattern portion BM may not be composed of the color filters 321 through 323 described above, but may be formed of an organic light blocking material, for example, may be formed by coating and exposing an organic light blocking material. For ease of description, a case where the light blocking pattern portion BM has a structure in which the first light blocking pattern area 321b, the third light blocking pattern area 323b, and the second light blocking pattern area 322b may be sequentially stacked on each other in the third direction DR3 will be described below. The light blocking pattern portion BM may absorb all of the first light, the second light, and the third light through the above-described configuration.

The filler 500 may be disposed between the light emitting part 100 and the color filter part 300 to fill the space between the light emitting part 100 and the color filter part 300 as described above. Specifically, in some embodiments, the filler 500 may contact (e.g., directly contact) the second capping layer CPL2 of the light emitting part 100 and the color filter member 320 of the color filter part 300. However, the disclosure is not limited thereto.

In some embodiments, the filler 500 may be made of a material whose extinction coefficient may be substantially zero. A refractive index and an extinction coefficient may be correlated, and the extinction coefficient decreases as the refractive index decreases. In case that the refractive index is about 1.7 or less, the extinction coefficient may converge to substantially zero. In some embodiments, the filler 500 may be made of a material having a refractive index of about 1.7 or less. Accordingly, light provided by the self-light emitting elements can be prevented from being absorbed by the filler 500 as it passes through the filler 500, or the absorption of the light by the filler 500 can be minimized. In some embodiments, the filler 500 may be made of an organic material having a refractive index in a range of about 1.4 to about 1.6.

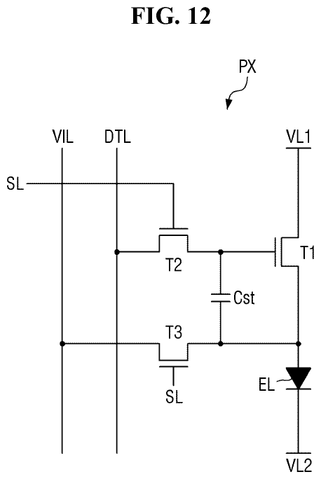

FIG. 12 is a schematic diagram of an equivalent circuit of a pixel of the display device 1 according to the embodiment.

Referring to FIG. 12, a pixel PX of the display device 1 according to the embodiment may include a light emitting diode EL, multiple transistors T1 through T3, and a storage capacitor Cst.

The light emitting diode EL emits light according to a current supplied through a first transistor T1. The light emitting diode EL may include a first electrode (e.g., an anode), a second electrode (e.g., a cathode), and at least one light emitting element disposed between them. The light emitting element may emit light in a specific wavelength range in response to electrical signals received from the first electrode and the second electrode.

An end of the light emitting diode EL may be electrically connected to a source electrode of the first transistor T1, and another end may be electrically connected to a second voltage line VL2 to which a low potential voltage (e.g., a second power supply voltage) lower than a high potential voltage (e.g., a first power supply voltage) of a first voltage line VL1 may be supplied.

The first transistor T1 adjusts a current flowing from the first voltage line VL1, to which the first power supply voltage may be supplied, to the light emitting diode EL according to a voltage difference between a gate electrode and the source electrode. For example, the first transistor T1 may be a driving transistor for driving the light emitting diode EL. The first transistor T1 may have the gate electrode electrically connected to a source electrode of a second transistor T2, the source electrode electrically connected to the first electrode of the light emitting diode EL, and a drain electrode electrically connected to the first voltage line VL1 to which the first power supply voltage may be applied.

The second transistor T2 may be turned on by a scan signal of a scan line SL to connect a data line DTL to the gate electrode of the first transistor T1. The second transistor T2 may have a gate electrode electrically connected to the scan line SL, the source electrode electrically connected to the gate electrode of the first transistor T1, and a drain electrode electrically connected to the data line DTL.

A third transistor T3 may be turned on by the scan signal of the scan line SL to connect an initialization voltage line VIL to the an end of the light emitting diode EL. The third transistor T3 may have a gate electrode electrically connected to the scan line SL, a drain electrode electrically connected to the initialization voltage line VIL, and a source electrode electrically connected to the an end of the light emitting diode EL or the source electrode of the first transistor T1.

In an embodiment, the source electrode and the drain electrode of each of the transistors T1 through T3 are not limited to the above description, and the opposite may also be the case. Each of the transistors T1 through T3 may be formed as a thin-film transistor. Although a case where each of the transistors T1 through T3 may be an N-type metal oxide semiconductor field effect transistor (MOSFET) has been described in FIG. 12, the disclosure is not limited thereto. For example, each of the transistors T1 through T3 may also be formed as a P-type MOSFET, or some of them may be formed as N-type MOSFETs, and another may be formed as a P-type MOSFET.

The storage capacitor Cst may be formed between the gate electrode and the source electrode of the first transistor T1. The storage capacitor Cst stores a difference voltage between a gate voltage and a source voltage of the first transistor T1.

In the embodiment of FIG. 12, the gate electrodes of the second transistor T2 and the third transistor T3 may be electrically connected to the same scan line SL. Therefore, the second transistor T2 and the third transistor T3 may be simultaneously turned on by a scan signal transmitted from the same scan line. However, the disclosure is not limited to this case. The gate electrode of the second transistor T2 may also be electrically connected to any one scan line SL, and the gate electrode of the third transistor T3 may be electrically connected to another scan line SL different from the above scan line SL.

In some embodiments, the pixel PX of FIG. 12 may include any one of the first through third light emitting areas ELA_1 through ELA_3 of FIG. 4 described above. For example, any one of three pixels PX may include the first light emitting area ELA_1, another one of the three pixels PX may include the second light emitting area ELA_2, and another one of the pixels PX may include the third light emitting area ELA_3.

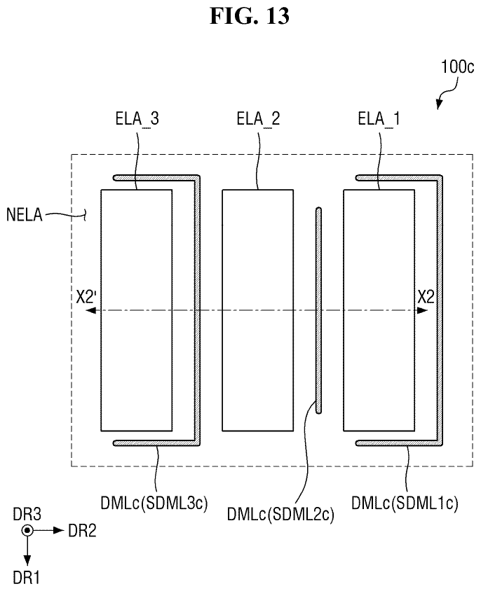

FIG. 13 is a modified plan view corresponding to area A1 of FIG. 3, more specifically, a modified schematic plan view of a light emitting part 100c and a dummy layer DMLc included in a modified version of the display device of FIG. 3.

A display device of FIG. 13 is different from the display device of FIG. 4 described above in the positions of light emitting areas, the shapes of the light emitting areas, the position of the dummy layer DMLc, and the shape of the dummy layer DMLc. Therefore, these differences will be described as follows.

As illustrated in FIG. 13, a first light emitting area ELA_1, a second light emitting area ELA_2, and a third light emitting area ELA_3 may be arranged in line in the reverse of the second direction DR2 (hereinafter, referred to as a second reverse direction). Here, the first color filter 321 described above may be disposed in the first light emitting area ELA_1, the second color filter 322 described above may be disposed in the second light emitting area ELA_2, and the third color filter 323 described above may be disposed in the third light emitting area ELA_3.

The dummy layer DMLc may include a first sub-dummy layer SDML1c, a second sub-dummy layer SDML2c, and a third sub-dummy layer SDML3c.

The first sub-dummy layer SDML1c may be disposed around the first light emitting area ELA_1 to face three surfaces of the first light emitting area ELA_1. The first sub-dummy layer SDML1c may have, for example, a ‘]’ shape.

The second sub-dummy layer SDML2c may be disposed between the first light emitting area ELA_1 and the second light emitting area ELA_2.

The third sub-dummy layer SDML3c may be disposed around the third light emitting area ELA_3 to face three surfaces of the third light emitting area ELA_3. At least a portion of the third sub-dummy layer SDML3c may be disposed between the third light emitting area ELA_3 and the second light emitting area ELA_2. The third sub-dummy layer SDML3 may have, for example, a ‘]’ shape.

A schematic cross-sectional view taken along line X2-X2′ of FIG. 13 may be the same as the schematic cross-sectional view of FIG. 6 described above.

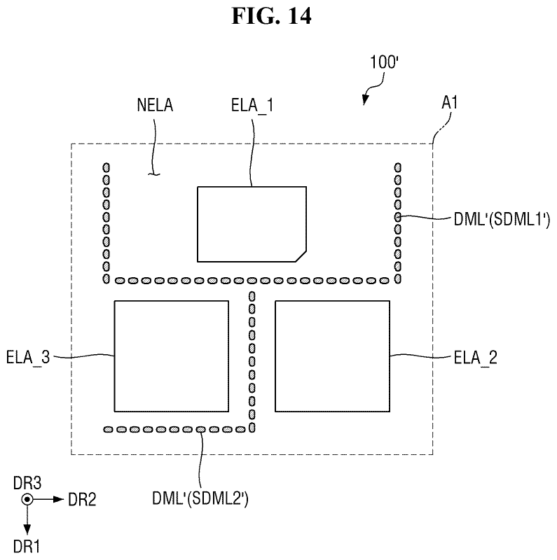

FIG. 14 is a plan view corresponding to area A1 of FIG. 3, more specifically, a modified schematic plan view of a light emitting part 100′ and a dummy layer DML′ included in a modified version of the display device of FIG. 3.

A display device of FIG. 14 may be different from the display device of FIG. 4 described above in the shape of the dummy layer DML. Therefore, this difference will be described as follows.

As illustrated in FIG. 14, the dummy layer DML′ may have a dotted shape. For example, a first sub-dummy layer SDML1′ may be disposed in a dotted (or broken) shape around a first light emitting area ELA_1, and a second sub-dummy layer SDML2′ may be disposed in a dotted shape around a third light emitting area ELA_3.

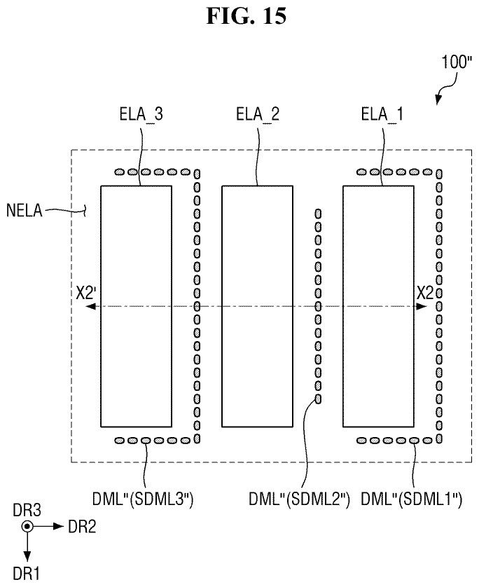

FIG. 15 is a modified plan view corresponding to area A1 of FIG. 3, more specifically, a modified schematic plan view of a light emitting part 100″ and a dummy layer DML included in the display device of FIG. 3.

A display device of FIG. 15 may be different from the display device of FIG. 13 described above in the shape of the dummy layer DML″. Therefore, this difference will be described as follows.

As illustrated in FIG. 15, the dummy layer DML″ may have a dotted shape. For example, a first sub-dummy layer SDML1″ may be disposed in a dotted shape around a first light emitting area ELA_1, and a second sub-dummy layer SDML2″ may be disposed in a dotted shape between the first light emitting area ELA_1 and a second light emitting area ELA_2. A third sub-dummy layer SDML3″ may be disposed in a dotted shape around a third light emitting area ELA_3.

The dotted dummy layer DML″ may be more effective in preventing lateral leakage current in display devices having fine pixels, such as augmented reality (AR) and virtual reality (VR) display devices. For example, since greater resistance may be generated in a current path between adjacent pixels by the dotted dummy layer DML″, the dotted dummy layer DML″ can more effectively reduce the lateral leakage current in display devices having a fine pixel structure in which a distance between adjacent pixels may be considerably short.

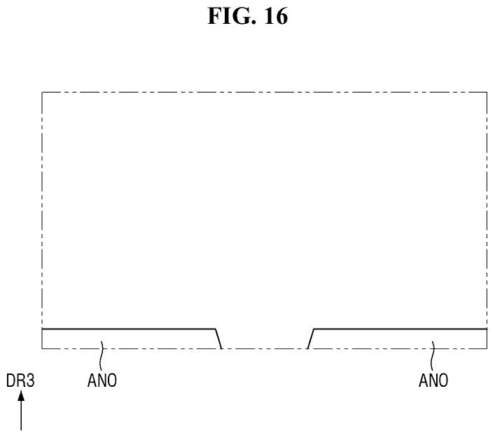

FIGS. 16 through 24 are schematic process cross-sectional views for explaining a method of fabricating a display device according to an embodiment. For example, FIGS. 16 through 24 may be schematic process cross-sectional views for explaining a method of fabricating the display device illustrated in FIG. 7 described above.

First, as illustrated in FIG. 16, a substrate 110 on which anodes ANO are disposed may be prepared.

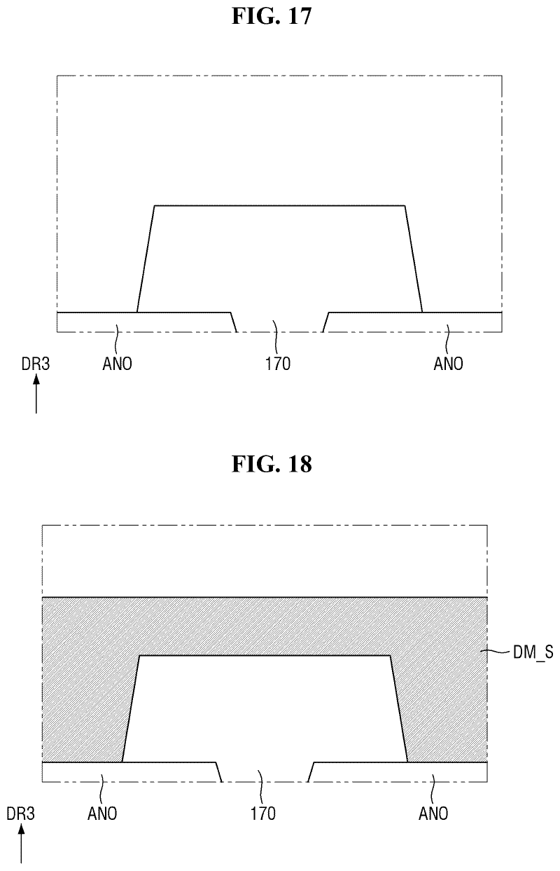

As illustrated in FIG. 17, a pixel defining layer 170 may be disposed on the anodes ANO. For example, the pixel defining layer 170 may be disposed in a non-light emitting area NELA to overlap edges of the anodes ANO.

As illustrated in FIG. 18, an inorganic material which may be a raw material for a dummy layer DML may be deposited on the entire surface of the substrate 110 including the pixel defining layer 170 and the anodes ANO. Accordingly, an inorganic material layer DM_S may be formed to cover the entire surface of the substrate 110 including the pixel defining layer 170 and the anodes ANO. For example, an inorganic material may be deposited on the substrate 110 at a temperature of about 360° C. or lower to form the inorganic material layer DM_S (e.g., low-temperature inorganic material layer). According to an embodiment, the inorganic material layer DM_S may be made of a material including at least one of SiNₓ, SiOₓ, and SiON. According to an embodiment, the above-described inorganic material layer DM_S may be deposited on the substrate 110 through a chemical vapor deposition (CVD) process. Therefore, only NF₃ excluding O₂ may be used in the deposition process of the inorganic material layer DM_S. Here, a chamber in which the substrate 110 including the inorganic material layer DM_S is placed may be maintained in a high-vacuum and high-power (e.g., high-RF power) state during the deposition process of the inorganic material layer DM_S.

According to an embodiment, the inorganic material layer DM_S may include, for example, silicon-rich SiNₓ. A flow rate (sccm) ratio between SiH₄ gas and NH₃ gas used to form the inorganic material layer DM_S may be about 4:1 or higher. As a specific example, a flow rate of SiH₄ gas may be four or more times a flow rate of NH₃ gas. The inorganic material layer DM_S fabricated in such an atmosphere inside the chamber may have a yellowish color.

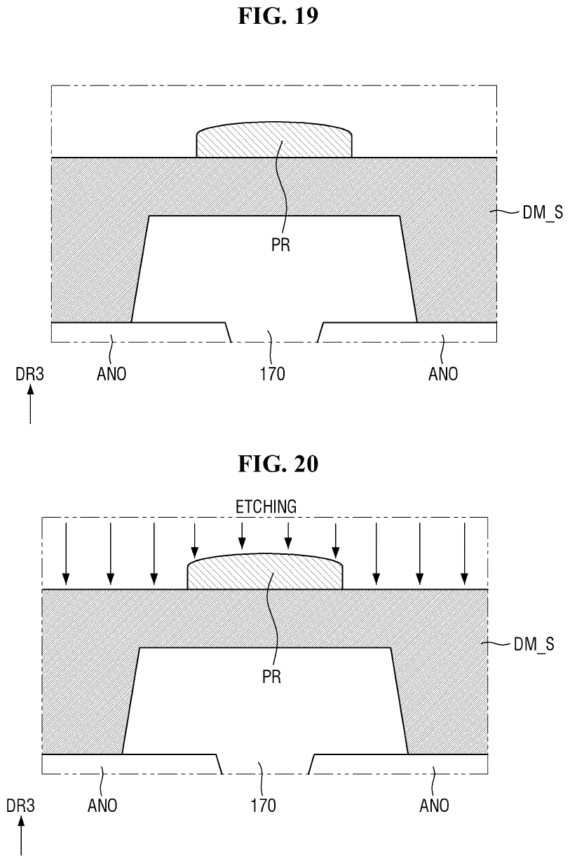

As illustrated in FIG. 19, a photoresist pattern PR may be disposed on the inorganic material layer DM_S. For example, the photoresist pattern PR may be disposed on the inorganic material layer DM_S to overlap the pixel defining layer 170. The photoresist pattern PR may define a portion of the inorganic material layer DM_S which may be to be used as the dummy layer DML.

As illustrated in FIG. 20, an etching process may be performed using the photoresist pattern PR as a mask. The etching process may be performed using a dry etching method. As another example, the etching process may be performed using a wet etching method.

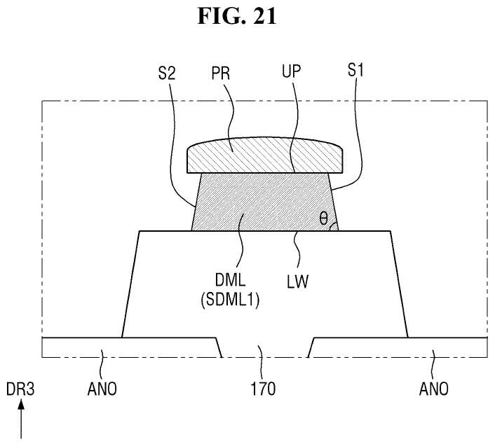

In case that the above etching process is performed and completed, the dummy layer DML may be formed between the pixel defining layer 170 and the photoresist pattern PR as illustrated in FIG. 21. The dummy layer DML may have a large taper angle θ in a range of about 65 to about 80 degrees as described above.

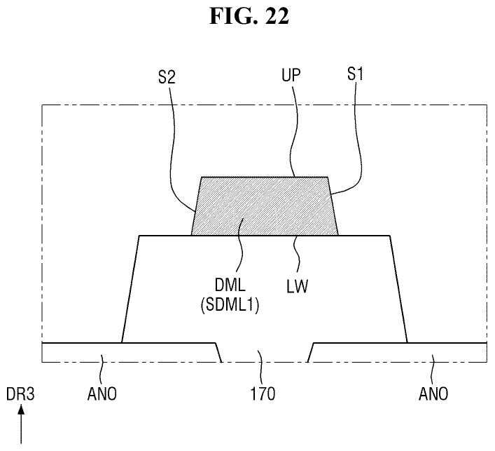

As illustrated in FIG. 22, the photoresist pattern PR may be removed. For example, the photoresist pattern PR may be removed by a stripping solution.

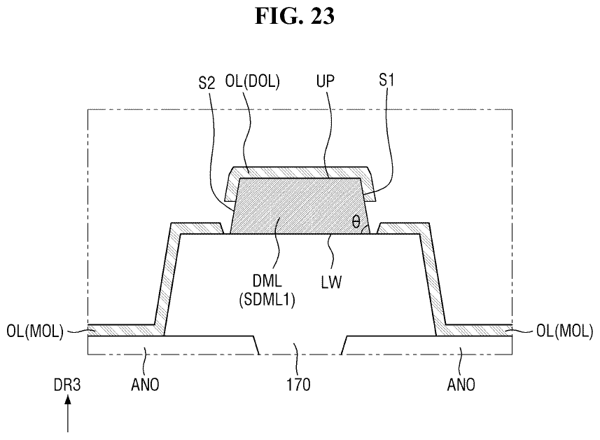

As illustrated in FIG. 23, a light emitting layer OL may be deposited on the substrate 110 including the dummy layer DML. Here, since the dummy layer DML has a fairly large taper angle θ, the light emitting layer OL may be broken around the dummy layer DML. Accordingly, the light emitting layer OL may be divided into a main light emitting layer MOL on the anodes ANO and a dummy light emitting layer DOL on the dummy layer DML.

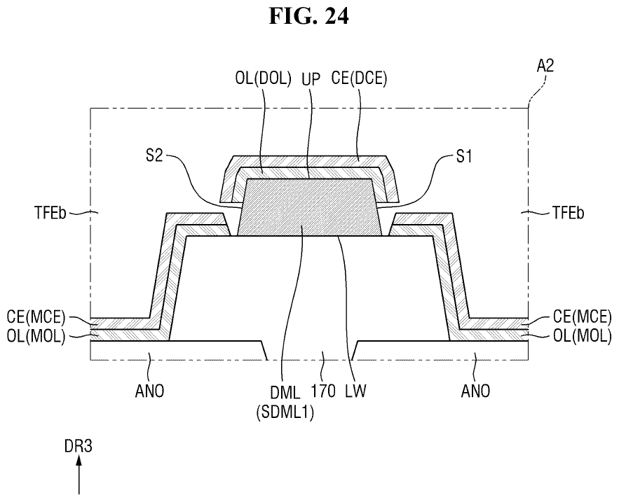

As illustrated in FIG. 24, a cathode CE may be disposed on the light emitting layer OL. Here, since the dummy layer DML has a fairly large taper angle θ, the cathode CE may be broken around the dummy layer DML. Accordingly, the cathode CE may be divided into a main cathode MCE on the main light emitting layer MOL and a dummy cathode DCE on the dummy layer DML.

As illustrated in FIG. 7 described above, a first capping layer CPL1, a lower inorganic layer TFEa, an organic layer TFEb, and an upper inorganic layer TFEc may be sequentially formed on the cathode CE.

As illustrated in FIG. 6 described above, a wavelength conversion member WC may be disposed on the upper inorganic layer TFEc.

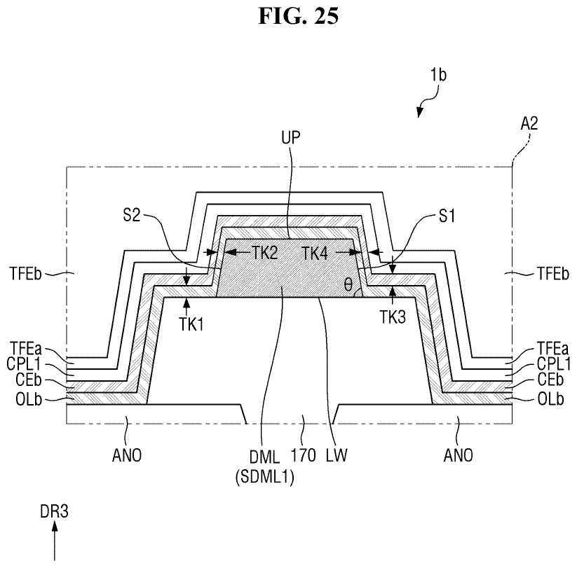

FIG. 25 is a schematic cross-sectional view of a display device 1 according to an embodiment.

The display device 1b of FIG. 25 may be different from the display device 1b of FIG. 7 described above in the shape of a light emitting layer OLb and a cathode CEb. Therefore, this difference will be described as follows.

As illustrated in FIG. 25, the light emitting layer OLb may be continuously disposed on anodes ANO, a pixel defining layer 170, and a dummy layer DML. In other words, the light emitting layer OLb may be continuous without being broken around the dummy layer DML. Here, a portion of the light emitting layer OLb which may be disposed on a first side surface S1 of the dummy layer DML along the first side surface S1 may have a smaller thickness than other portions of the light emitting layer OLb. For example, a thickness TK2 of the light emitting layer OLb on the second side surface S2 of the dummy layer DML may be smaller than a thickness TK1 of the light emitting layer OLb on the pixel defining layer 170 (or the anodes ANO or an upper surface of the dummy layer DML). Likewise, a thickness of the light emitting layer OLb on a first side surface S1 of the dummy layer DML may be smaller than a thickness of the light emitting layer OLb on the pixel defining layer 170 (or the anodes ANO or the upper surface of the dummy layer DML).

The cathode CEb may be continuously disposed on the anodes ANO, the pixel defining layer 170, and the dummy layer DML. In other words, the cathode CEb may be continuous without being broken around the dummy layer DML. Here, a portion of the cathode CEb which may be disposed on the first side surface S1 of the dummy layer DML along the first side surface S1 may have a smaller thickness than other portions of the cathode CEb. For example, a thickness TK4 of the cathode CEb on the first side surface S1 of the dummy layer DML may be smaller than a thickness TK3 of the cathode CEb on the pixel defining layer 170 (or the anodes ANO or the upper surface of the dummy layer DML). Likewise, a thickness of the cathode CEb on the second side surface S2 of the dummy layer DML may be smaller than a thickness of the cathode CEb on the pixel defining layer 170 (or the anodes ANO or the upper surface of the dummy layer DML).

Since the thickness of the light emitting layer OLb around the dummy layer DML may be relatively small, a large resistance may be generated in a current path between pixels disposed adjacent to each other with the dummy layer DML disposed between them. Accordingly, lateral leakage current between the adjacent pixels can be minimized.

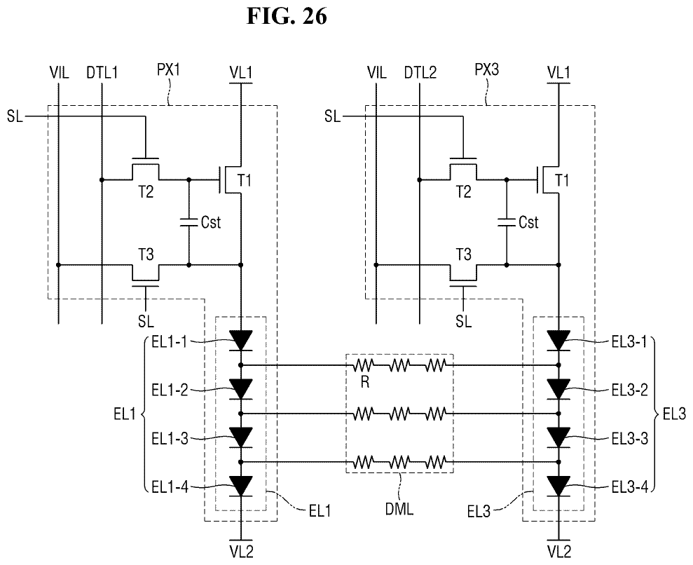

FIG. 26 is a schematic diagram for explaining the effect of preventing lateral leakage current between adjacent pixels by a dummy layer DML in a display device according to an embodiment.

As illustrated in FIG. 26, a first pixel PX1 may be a pixel including the first light emitting area ELA_1 described above, and a third pixel PX3 may be a pixel including the third light emitting area ELA_3 described above. The first pixel PX1 and the third pixel PX3 may be adjacent to each other. Here, the first pixel PX1 and the third pixel PX3 may be pixels included in a pixel part or may be pixels included in different pixel parts. For example, the first pixel PX1 may be any one of three pixels included in a first pixel part, and the third pixel PX3 may be any one of three pixels included in a third pixel part.

Here, a first light emitting diode EL1 of the first pixel PX1 may include multiple light emitting elements EL1-1 through EL1-4 electrically connected in series between a first transistor T1 provided in the first pixel PX1 and a second voltage line VL2, and a third light emitting diode EL3 of the third pixel PX3 may include multiple light emitting elements EL3-1 through EL3-4 electrically connected in series between a transistor T1 included in the third pixel PX3 and a second voltage line VL2. In FIG. 26, as an example, the first light emitting diode EL1 and the third light emitting diode EL3 may be illustrated as 4-tandem light emitting diodes, each including four light emitting elements.

As described above, since a light emitting layer OL may be broken (or electrically disconnected) between the first light emitting area ELA_1 and a second light emitting area ELA_2 (as well as between the first light emitting area ELA_1 and the third light emitting area ELA_3 and between the second light emitting area ELA_2 and the third light emitting area ELA_3) by the dummy layer DML, a large resistance may be generated between the light emitting elements EL1-1 through EL1-4 of the first light emitting diode EL1 and the light emitting elements EL3-1 through EL3-4 of the third light emitting diode EL3. In other words, an equivalent circuit can be established as if a large number of resistors R were disposed between the first pixel PX1 including the first light emitting area ELA_1 and the third pixel PX3 including the third light emitting area ELA_3. Accordingly, lateral leakage current between the first pixel PX1 and the third pixel PX3 can be minimized. For example, the lateral leakage current between the first pixel PX1 providing blue light and the third pixel PX3 providing red light can be minimized. Therefore, at a time in case that the third light emitting diode EL3 of the third pixel PX3 is turned on and the first light emitting diode EL1 of the first pixel PX1 is turned off, the problem that the first light emitting diode EL1 of the first pixel PX1 is turned on by the lateral leakage current from the turned-on third pixel PX3 can be solved. If the lateral leakage current from the third pixel PX3 is provided to the first pixel PX1 at a time in case that the third pixel PX3 is turned on, for example, red light from the third pixel PX3 and blue light from the pixel PX1 may be mixed with each other. Due to the lateral leakage current from the third pixel PX3, sufficient current (e.g., driving current) may not be supplied to the third light emitting diode EL3 of the third pixel PX3, thereby deteriorating the color purity of the red light. However, if the light emitting layer OL may be partially broken by the dummy layer DML disposed between adjacent pixels as in the embodiment, the lateral leakage current may be minimized due to increased resistance. Accordingly, the color mixing phenomenon and the color purity deterioration phenomenon can be prevented, thereby improving the image quality of the display device.

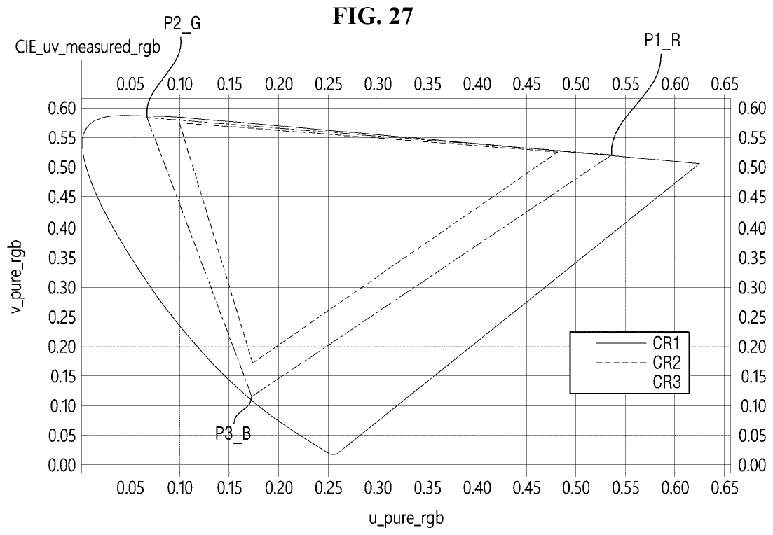

FIG. 27 is a chromaticity distribution schematic diagram.

A first figure CR1 may be a figure representing a reference color space (e.g., a color space or color gamut of a visible light region), a second figure CR2 may be a figure representing a color space (or a color gamut) defined by Digital Cinema Initiatives (DCI)-P3, and a third figure CR3 may be a figure representing a color space (or a color gamut) defined based on measurements of an image of a display device according to an embodiment.

The third figure CR3 may include three vertices. A first vertex P1_R may represent a red region, a second vertex P2_G may represent a green region, and a third vertex P3_B may represent a blue region.

As illustrated in FIG. 27, the third figure CR3 including the first vertex P1_R may surround the second figure CR2 and have a larger area than the second figure CR2. Therefore, the display device according to the embodiment can satisfy the color purity defined in DCI-P3. For example, in the display device according to the embodiment, the color purity of red can be improved, and color mixing can be prevented. For example, the display device according to the embodiment may provide high color purity corresponding to 99.2% of the color space defined by DCI-P3. The display device according to the embodiment may show a low color mixing rate of 0.3%.

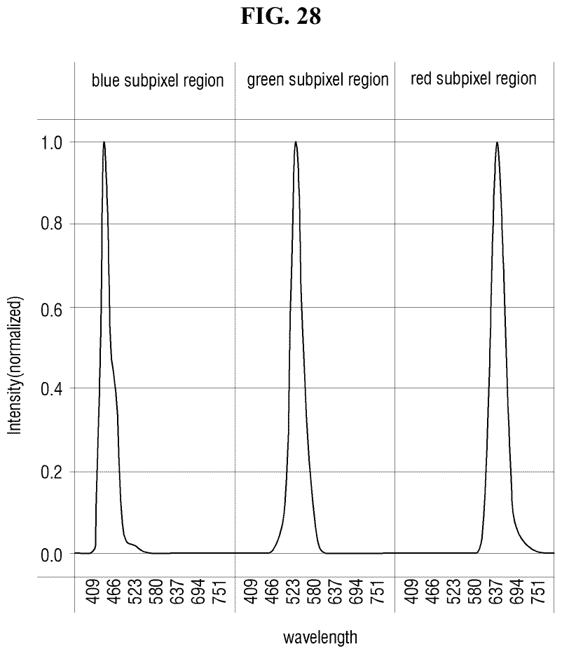

FIG. 28 illustrates a peak value for each wavelength of a display device 1 according to an embodiment.

As illustrated in FIG. 28, in the display device 1 according to the embodiment, the peak value for each wavelength may be maintained at a high value with almost no noise in a red wavelength region R255, a green wavelength region G255, and a blue wavelength region B255. Therefore, in the display device 1 according to the embodiment, color purity can be improved.

According to an embodiment, since a light emitting layer OL and a wavelength conversion member WC are disposed adjacent to each other, there is a possibility of color mixing between adjacent pixels. However, since a dummy layer DML is disposed on a pixel defining layer between adjacent pixels, the color mixing phenomenon can be minimized.

According to an embodiment, in case that the dummy layer DML has a color different from the colors provided from adjacent pixels, it can block light provided from the light emitting layer OL of the adjacent pixels, thereby further improving the color mixing prevention effect. For example, in case that the light emitting layer OL of the pixels provide blue light, the dummy layer DML may have a color (e.g., red or green) different from blue. It may be difficult for blue light emitted from the light emitting layer OL of a pixel to enter a wavelength conversion layer corresponding to an adjacent pixel. This may be because the dummy layer DML of a color different from blue may be disposed on the pixel defining layer between the adjacent pixels. Therefore, the problem that a pixel emits light during a light emission period of another pixel adjacent to the pixel can be solved. Ultimately, color mixing between adjacent pixels can be prevented, and color purity can be improved.

In a display device according to an embodiment, color mixing may be prevented, and color purity may be improved. Therefore, the image quality of the display device can be improved.

However, the effects of the disclosure are not restricted to the a set forth herein. The above and other effects of the disclosure will become more apparent to one of daily skill in the art to which the disclosure pertains by referencing the claims.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a first electrode on a substrate;
a pixel defining layer on the first electrode;
a dummy layer disposed on an uppermost surface of the pixel defining layer;
a light emitting layer on the first electrode and the dummy layer; and
a second electrode on the light emitting layer,
wherein an angle between a lower surface of the dummy layer which faces the pixel defining layer and a side surface of the dummy layer which is adjacent to the lower surface of the dummy layer is an acute angle.

2. The display device of claim 1, wherein the angle between the lower surface and the side surface of the dummy layer is in a range of about 65 to about 90 degrees.

3. The display device of claim 1, wherein the dummy layer has a trapezoidal cross section.

4. The display device of claim 3, wherein the dummy layer has a width that gradually decreases in a first direction from the lower surface of the dummy layer toward an upper surface of the dummy layer which faces the lower surface.

5. The display device of claim 1, wherein the dummy layer has a yellowish color.

6. The display device of claim 1, wherein
the pixel defining layer has a light emitting area disposed to correspond to a portion of the light emitting layer disposed on the first electrode, and
the dummy layer is disposed around the light emitting area in a plan view.

7. The display device of claim 6, wherein
the pixel defining layer defines a plurality of light emitting areas, and
at least a portion of the dummy layer is disposed between adjacent ones of the plurality of light emitting areas in a plan view.

8. The display device of claim 1, wherein the dummy layer has a line shape in a plan view.

9. The display device of claim 1, wherein the dummy layer has a dotted shape in a plan view.

10. The display device of claim 1, wherein the dummy layer comprises an inorganic material.

11. The display device of claim 10, wherein the dummy layer comprises at least one of SiNₓ, SiOₓ, and SiON.

12. The display device of claim 1, wherein the dummy layer has a thickness in a range of about 1000 to about 4000 Å.

13. The display device of claim 1, wherein a portion of the light emitting layer on the first electrode and a portion of the light emitting layer on the dummy layer are not electrically connected.

14. The display device of claim 13, wherein the light emitting layer comprises:
a main light emitting layer on the first electrode; and
a dummy light emitting layer disposed on the dummy layer,
wherein the dummy light emitting layer is separated from the main light emitting layer.

15. The display device of claim 1, wherein a portion of the second electrode that overlaps the first electrode in a plan view is electrically disconnected from a portion of the second electrode that overlaps the dummy layer in a plan view.

16. The display device of claim 15, wherein the second electrode comprises:
a main second electrode disposed on the light emitting layer to overlap the first electrode; and
a dummy second electrode disposed on the light emitting layer to overlap the dummy layer,
wherein the main second electrode is electrically disconnected from the dummy second electrode.

17. The display device of claim 1, further comprising:
a thin-film encapsulation layer on the second electrode,
wherein the thin-film encapsulation layer covers a broken portion of the light emitting layer.

18. The display device of claim 17, further comprising:
a capping layer between the second electrode and the thin-film encapsulation layer,
wherein the capping layer covers the broken portion of the light emitting layer.

19. The display device of claim 17, further comprising:
a wavelength conversion member on the thin-film encapsulation layer.

20. The display device of claim 1, wherein a portion of the light emitting layer which is disposed along the side surface of the dummy layer has a smaller thickness than other portions of the light emitting layer.

21. The display device of claim 1, wherein a portion of the second electrode which is disposed along the side surface of the dummy layer has a smaller thickness than other portions of the second electrode.

22. A method of fabricating a display device, the method comprising:
forming a first electrode on a substrate;
forming a pixel defining layer on the first electrode;
forming a dummy layer on an uppermost surface of the pixel defining layer;
forming a light emitting layer on the first electrode and on the dummy layer; and
forming a second electrode on the light emitting layer,
wherein an angle between a lower surface of the dummy layer which faces the pixel defining layer and a side surface of the dummy layer adjacent to the lower surface of the dummy layer is an acute angle.

23. The method of claim 22, wherein the forming of the dummy layer comprises:
forming an inorganic material layer by applying an inorganic material to an entire surface of the substrate which comprises the first electrode and the pixel defining layer;
placing a photoresist pattern on the inorganic material layer; and
forming the dummy layer on the uppermost surface of the pixel defining layer by selectively removing the inorganic material layer using the photoresist pattern as a mask.

24. The method of claim 22, wherein the angle between the lower surface and the side surface of the dummy layer is in a range of about 65 to about 90 degrees.

25. The method of claim 22, wherein the dummy layer has a trapezoidal cross section.

26. The method of claim 25, wherein the dummy layer has a width that gradually decreases in a first direction from the lower surface of the dummy layer toward an upper surface of the dummy layer which faces the lower surface.

27. The method of claim 22, wherein the dummy layer has a yellowish color.
